(19) United States
(12) Patent Application Publication
(10) Pub. No.: US 2025/0089340 A1
(43) Pub. Date: Mar. 13, 2025

(54) SEMICONDUCTOR DEVICE AND METHOD

(71) Applicant: Taiwan Semiconductor Manufacturing Co., Ltd., Hsinchu (TW)

(72) Inventors: Jet-Rung Chang, Hsinchu (TW); Ming-Hua Yu, Hsinchu (TW); Yi-Fang Pai, Hsinchu (TW)

(21) Appl. No.: 18/408,932

(22) Filed: Jan. 10, 2024

Related U.S. Application Data
(60) Provisional application No. 63/581,032, filed on Sep. 7, 2023.

(51) Int. Cl. H01L 29/45; H01L 21/285; H01L 21/8238; H01L 27/092; H01L 29/06; H01L 29/08; H01L 29/417; H01L 29/423; H01L 29/66; H01L 29/775

(52) U.S. Cl. CPC H10D 64/62; H01L 21/28518; H10D 30/014; H10D 30/43; H10D 30/6729; H10D 30/6735; H10D 62/121; H10D 62/151; H10D 64/017; H10D 84/017; H10D 84/0186; H10D 84/0188; H10D 84/038; H10D 84/85

(57) ABSTRACT

A semiconductor device and the method of forming the same are provided. The semiconductor device may comprise a first plurality of nanostructures, a second plurality of nanostructures over a substrate, a first gate stack extending between the nanostructures of the first plurality of nanostructures, a second gate stack extending between the nanostructures of the second plurality of nanostructures, a first source/drain region in contact with a first nanostructure of the first plurality of nanostructures, a second source/drain region in contact with a first nanostructure of the second plurality of nanostructures, wherein the second source/drain region may be separated from the first source/drain region, a silicide layer between the first source/drain region and the second source/drain region, and an isolation layer between the silicide layer and the substrate.

### PRIORITY CLAIM AND CROSS-REFERENCE

This application claims the benefit of U.S. Provisional Application No. 63/581,032, filed on Sep. 7, 2023, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 11D, 11E, 12A, 12B, 12C, 12D, 12E, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, 22C, 23A, 23B, 23C, 23D, 23E, 23F, 23G, 23H, and 23I are views of intermediate stages in the manufacturing of a semiconductor device including nano-FETs, in accordance with some embodiments.

FIGS. 24A, 24B, and 24C are views a semiconductor device including nano-FETs, in accordance with some embodiments.

FIGS. 25A, 25B, and 25C are views a semiconductor device including nano-FETs, in accordance with some embodiments.

FIGS. 26A, 26B, and 26C are views a semiconductor device including nano-FETs, in accordance with some embodiments.

FIGS. 27A, 27B, 27C, and 27D are views a semiconductor device including nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices having larger contact areas. For example, some embodiments provide nano-FETs including epitaxial source/drain regions and silicide layers formed on the epitaxial source/drain regions, wherein contact areas between the epitaxial source/drain regions and the silicide layers are large. By increasing contact areas the between epitaxial source/drain regions and the silicide layers, electrical resistance between the epitaxial source/drain regions and the silicide layers may be reduced. As a result, electrical resistance between the epitaxial source/drain regions and source/drain contacts may be reduced, thereby improving the performance of the semiconductor device.

Some embodiments discussed herein are described in the context of a semiconductor device including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

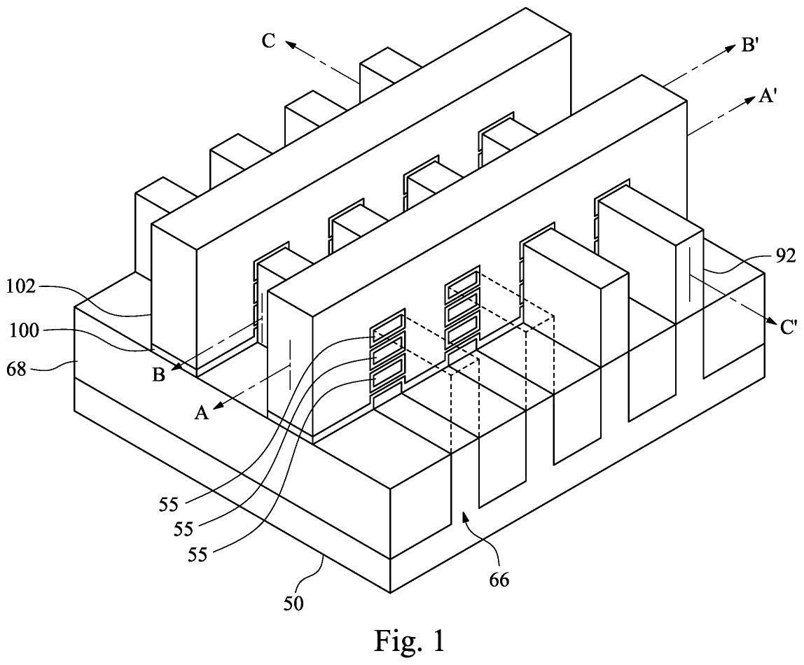

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68. Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A′ is along a longitudinal axis of a gate electrode 102 and in a direction, for example, perpendicular to the direction of current flow between the epitaxial source/drain regions 92 of a nano-FET. Reference cross-section B-B′ is parallel to the reference cross-section A-A′ and extends through epitaxial source/drain regions 92 of multiple nano-FETs. Reference cross-section C-C′ is perpendicular to the reference cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

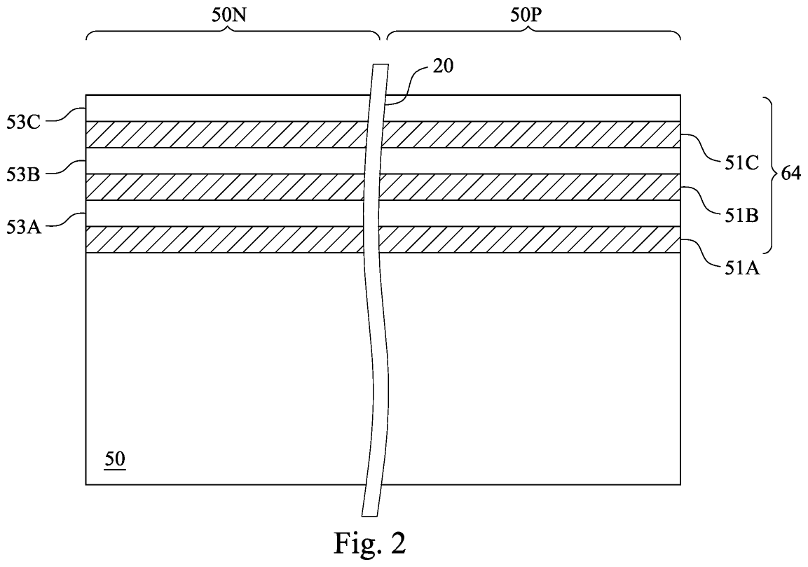

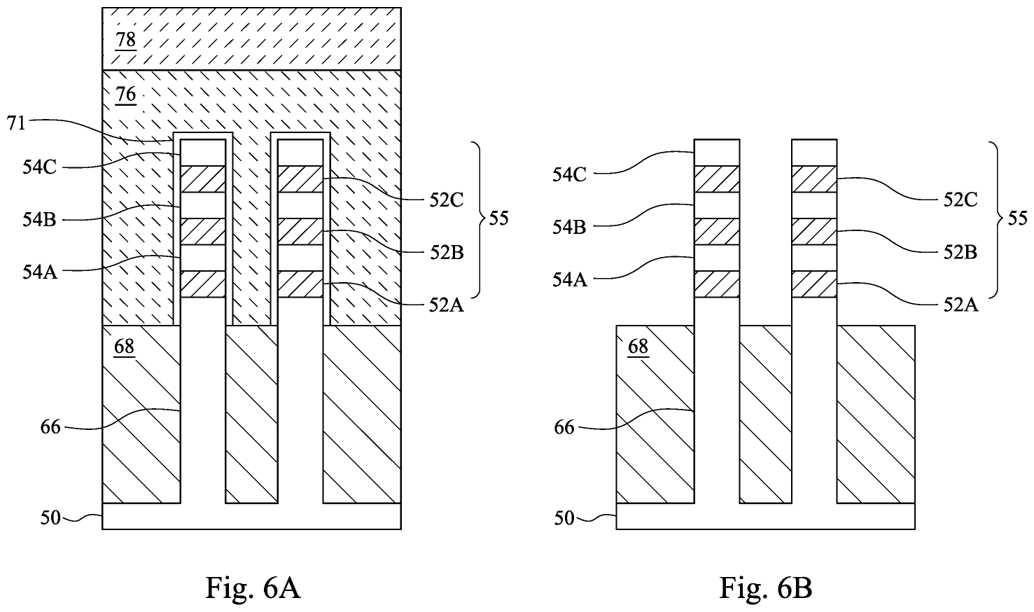

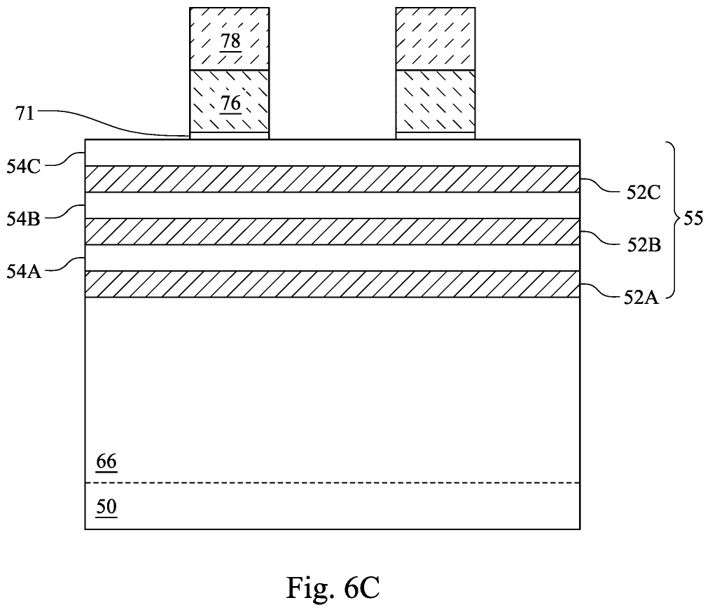

FIGS. 2 through 23C are views of intermediate stages in the manufacturing of a semiconductor device including nano-FETs, in accordance with some embodiments. FIGS. 2, 3, 4, 5, 6A, 7A, 8A, 9A, 10A, 11A, 12A, 13A, 14A, 15A, 16A, 17A, 18A, 19A, 20A, 21A, 22A, and 23A illustrate cross-sectional views along the reference cross-section A-A′ illustrated in FIG. 1. FIGS. 6B, 7B, 8B, 9B, 10B, 11B, 12B, 12D, 13B, 14B, 15B, 16B, 17B, 18B, 19B, 20B, 21B, 22B, and 23B illustrate cross-sectional views along the reference cross-section B-B′ illustrated in FIG. 1. FIGS. 6C, 7C, 8C, 9C, 10C, 11C, 11D, 11E, 12C, 12E, 13C, 14C, 15C, 16C, 17C, 18C, 19C, 20C, 21C, 22C, 23C, 23D, 23E, 23F, 23G, 23H, and 23I illustrate cross-sectional views along the reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon, carbon-doped silicon, or the like.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

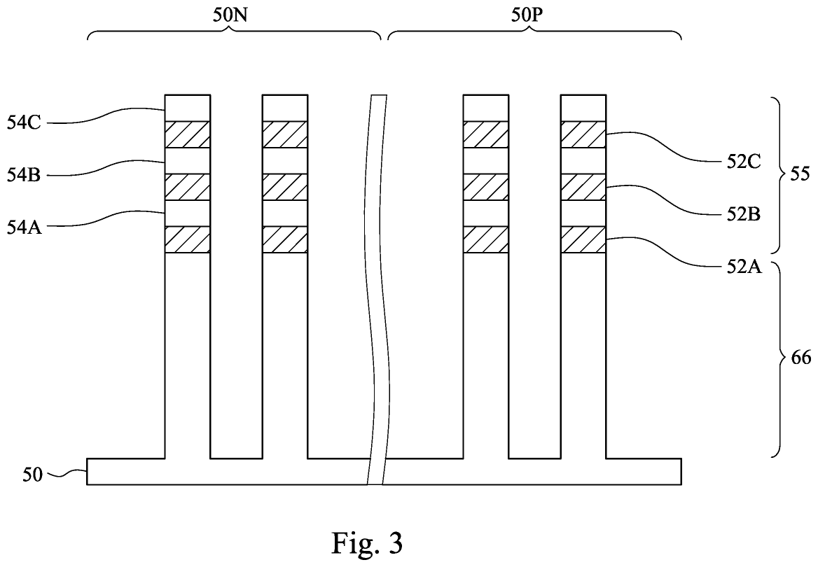

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

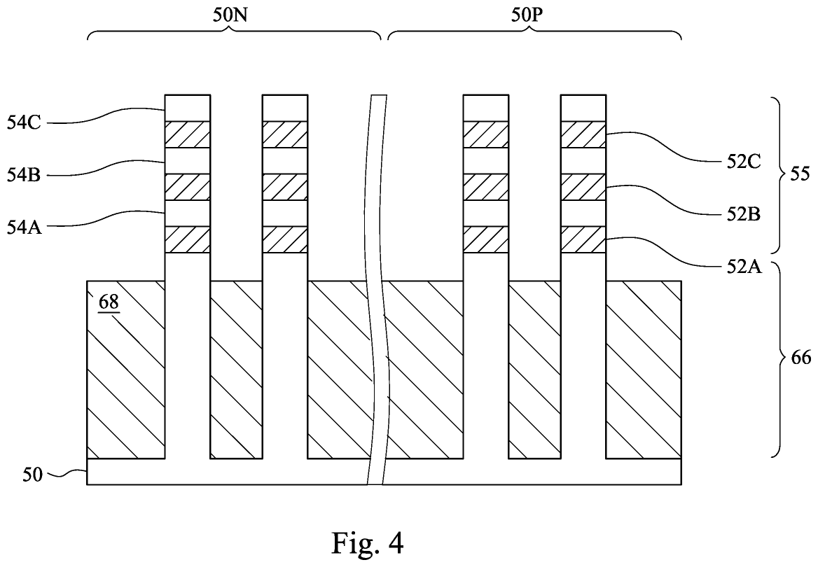

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes. In some embodiments, one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implantation, the photoresist may be removed, such as by an acceptable ashing process. After the implantations of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

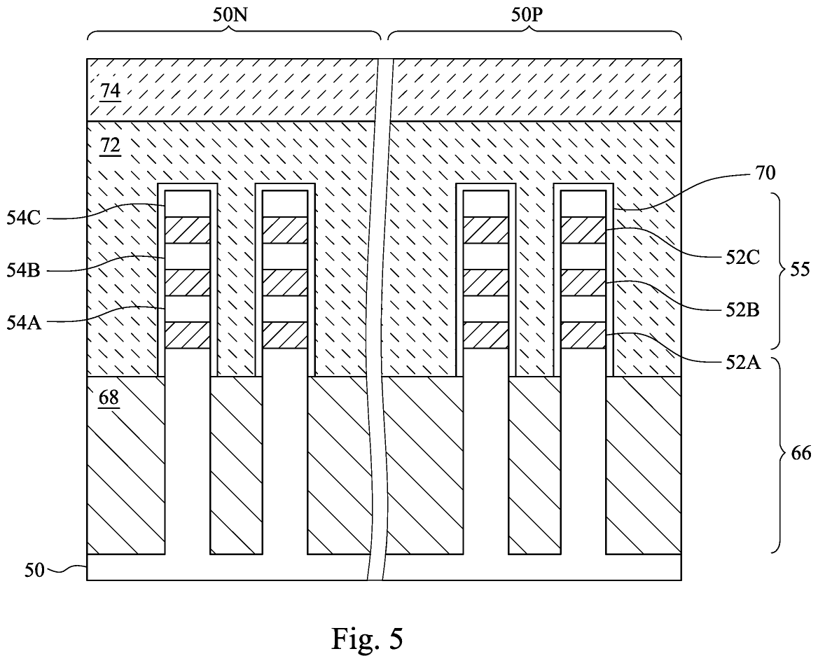

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 23I illustrate various additional steps in the manufacturing of the nano-FET devices, in accordance to some embodiments. FIGS. 6A through 23I illustrate features in either or both the n-type region 50N or the p-type region 50P. In FIGS. 6A through 6C, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

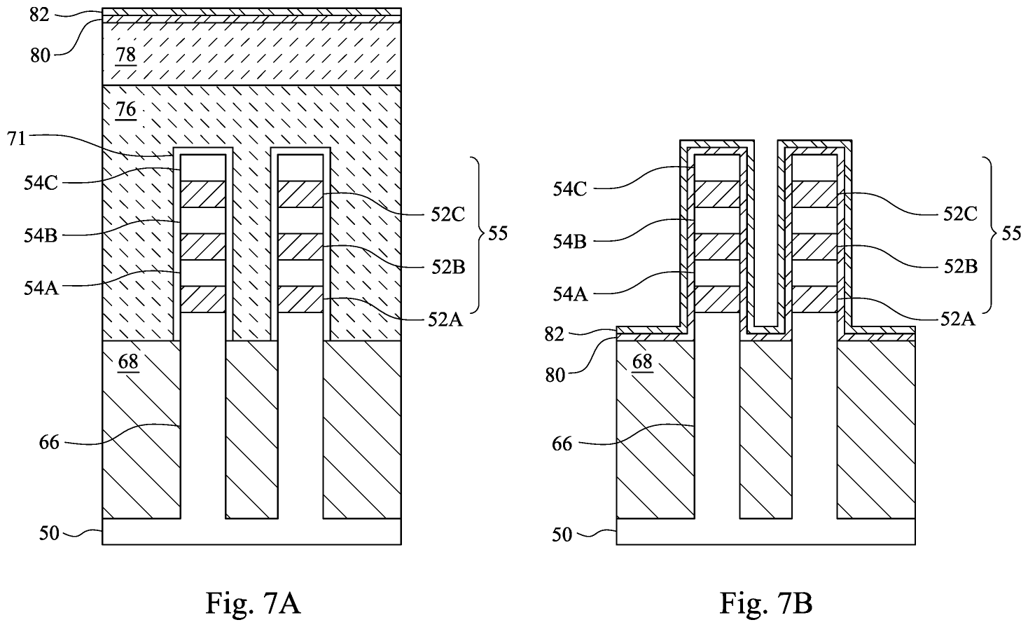

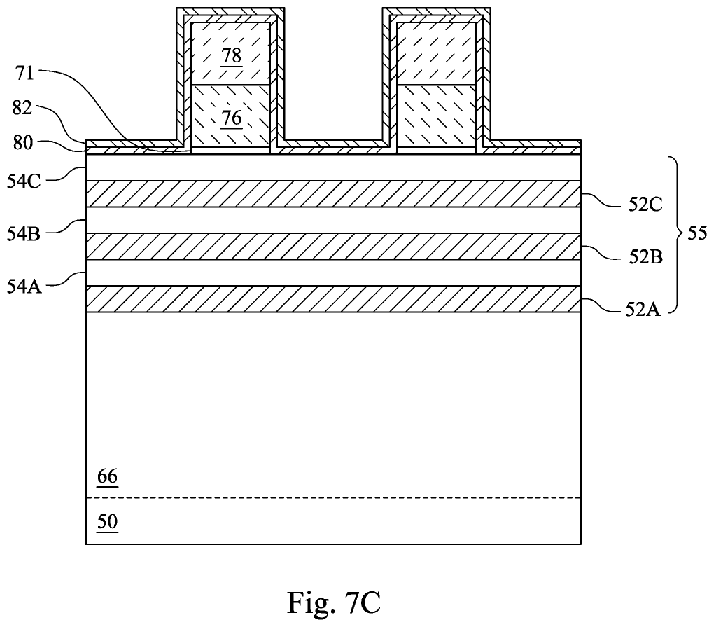

In FIGS. 7A through 7C, a first spacer layer 80 and a second spacer layer 82 are formed over the structures illustrated in FIGS. 6A through 6C. The first spacer layer 80 and the second spacer layer 82 will be subsequently patterned to act as spacers for forming self-aligned source/drain regions. In FIGS. 7A through 7C, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly-doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly-doped source/drain regions may have a concentration of impurities in a range from about 1×10¹⁵ atoms/cm³ to about 1×10¹⁹ atoms/cm³. An annealing may be used to repair implant damage and to activate the implanted impurities.

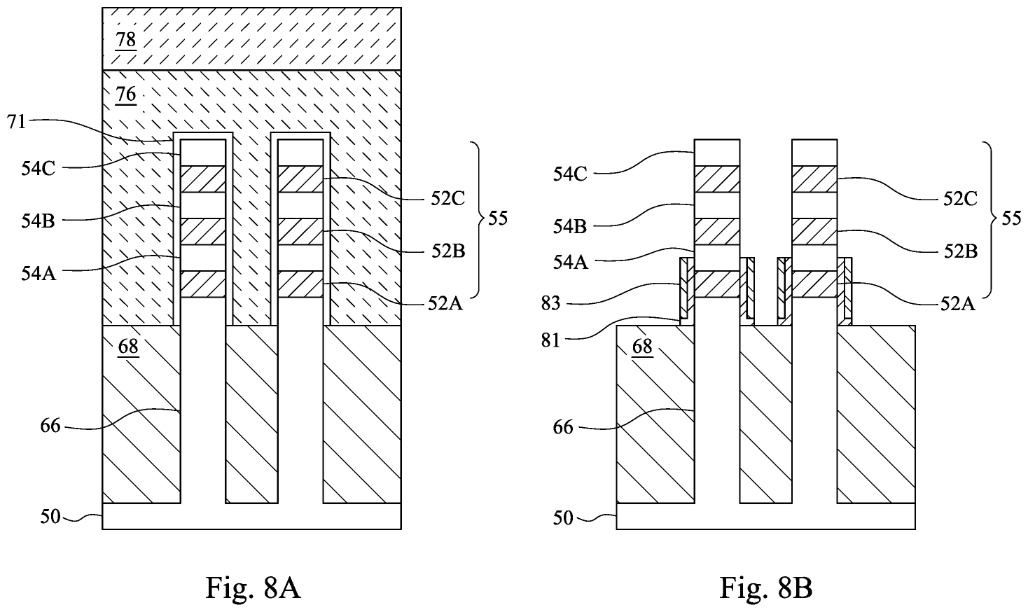

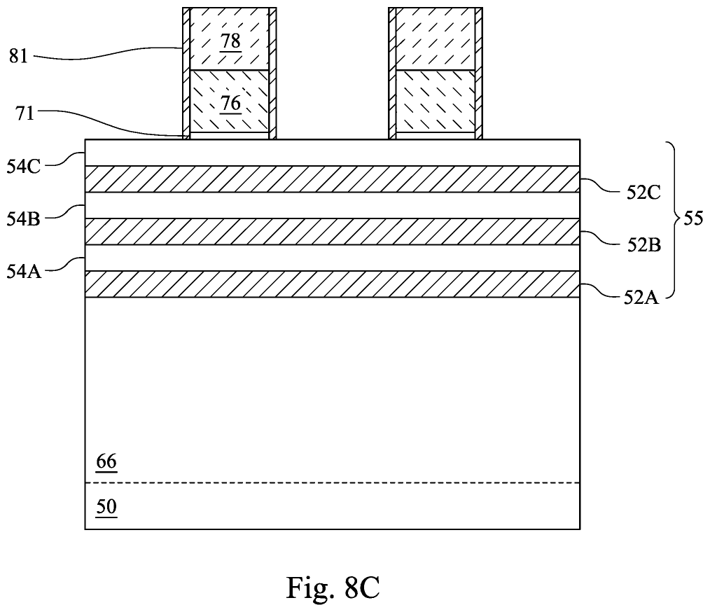

In FIGS. 8A through 8C, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8B. Thereafter, the second spacers 83 acts as a mask while etching exposed portions of the first spacer layer 80, thereby forming first spacers 81 as illustrated in FIGS. 8B and 8C.

As illustrated in FIG. 8B, portions of the first spacers 81 and the second spacers 83 may remain disposed on sidewalls of the fins 66 and/or nanostructures 55. As illustrated in FIG. 8C, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 71. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

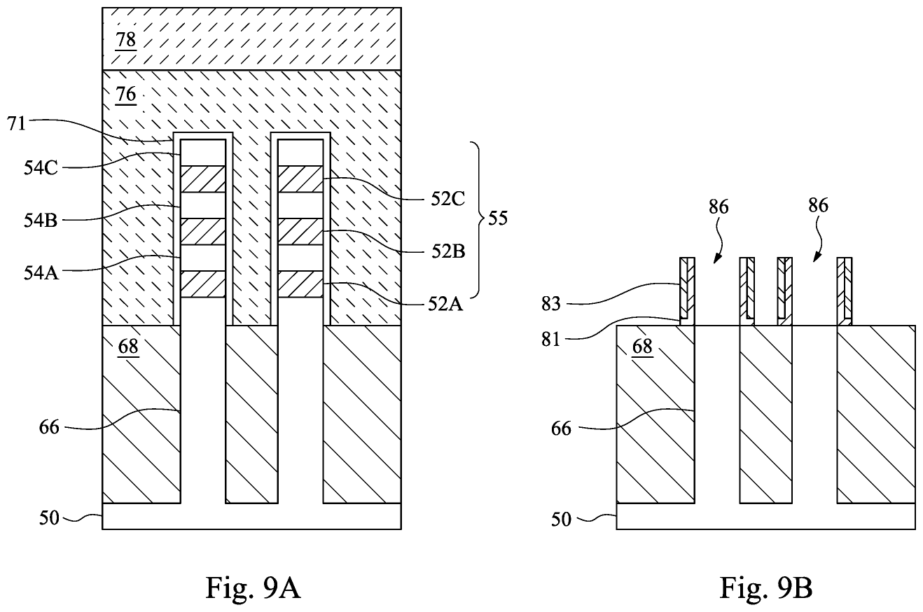

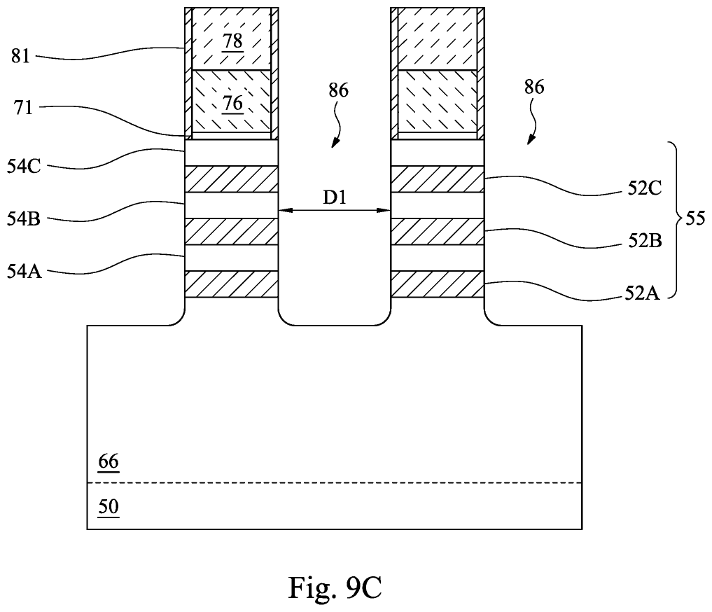

In FIGS. 9A through 9C, recesses 86 are formed in the fins 66, the nanostructures 55, and the substrate 50, in accordance with some embodiments. Epitaxial source/drain areas will be formed in the recesses 86. The recesses 86 may extend through the first nanostructures 52 and the second nanostructures 54, and into the substrate 50. As illustrated in FIG. 9B, top surfaces of the STI regions 68 may be level with bottom surfaces of the recesses 86. As illustrated in FIG. 9C, the recesses 86 may have a width D1 between two neighboring stacks of the second nanostructures 54, which may correspond to a width of a subsequently formed epitaxial source/drain area, as described in greater details below. In some embodiments, the width D1 may be in a range between about 15 nm to about 25 nm. In various embodiments, the fins 66 may be etched such that bottom surfaces of the recesses 86 are disposed below the top surfaces of the STI regions 68 or the like. The recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the recesses 86. A single etch process or multiple etch processes may be used to etch each layer of the nanostructures 55 and/or the fins 66. Timed etch processes may be used to stop the etching after the recesses 86 reach desired depths.

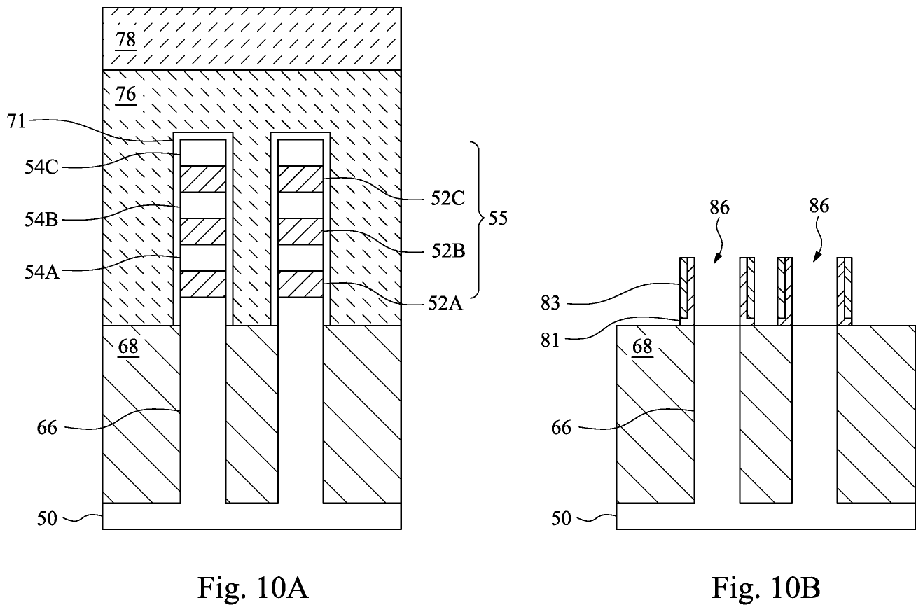

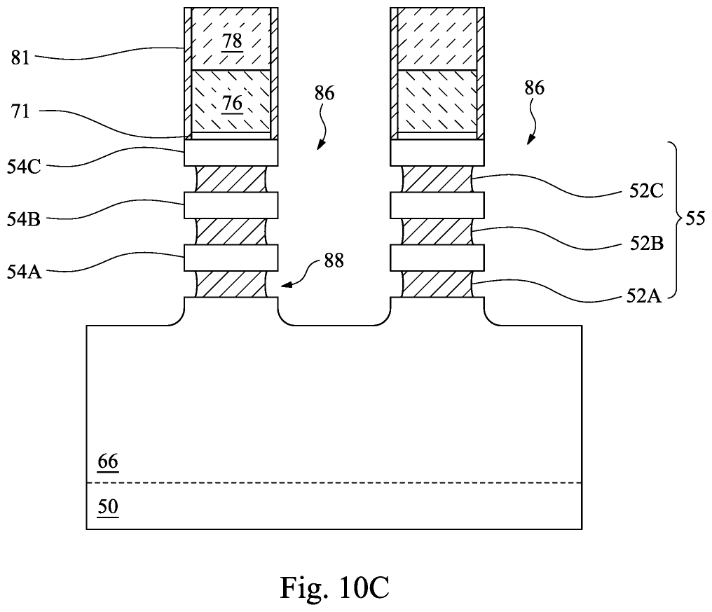

In FIGS. 10A through 10C, portions of sidewalls of the first nanostructures 52 exposed by the recesses 86 are etched to form sidewall recesses 88. Although sidewalls of the first nanostructures 52 adjacent the sidewall recesses 88 are illustrated as being concave in FIG. 10C, the sidewalls may be straight or convex. The sidewalls may be etched using isotropic etching processes, such as wet etching or the like. In an embodiment in which the first nanostructures 52 comprise silicon-germanium or the like, and the second nanostructures 54 comprise silicon, silicon carbide, or the like, tetramethylammonium hydroxide (TMAH), ammonium hydroxide (NH₄OH), or the like may be used to etch sidewalls of the first nanostructures 52.

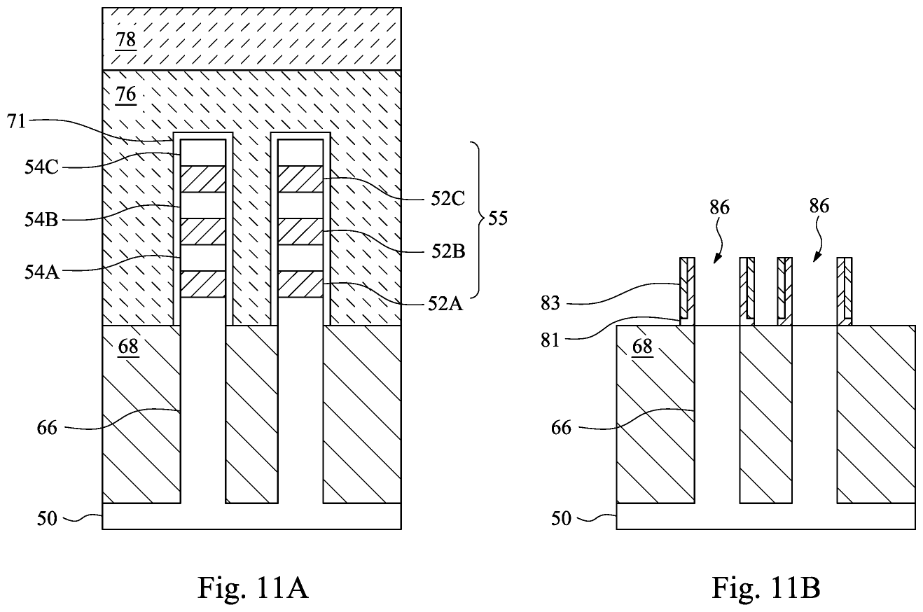

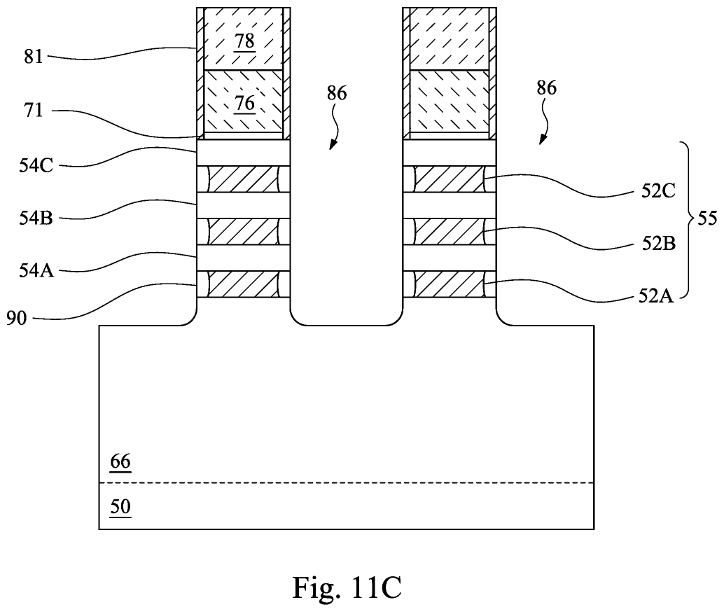

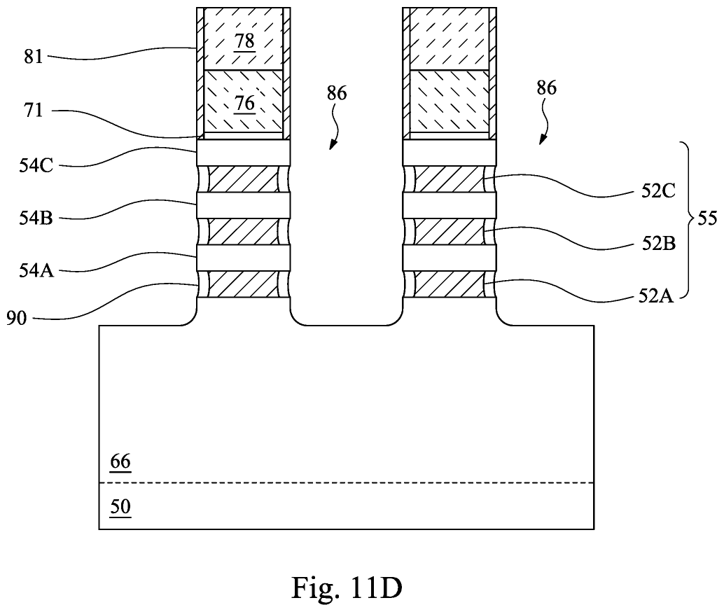

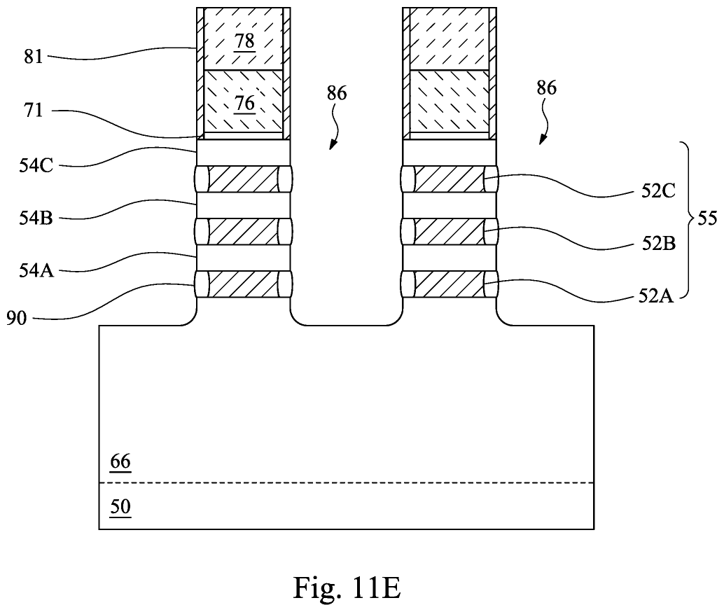

In FIGS. 11A through 11E, first inner spacers 90 are formed in the sidewall recess 88. As will be discussed in greater detail below, epitaxial source/drain regions will be formed in the recesses 86, while the first nanostructures 52 will be replaced with corresponding gate structures. The first inner spacers 90 may be used as isolation features to prevent damage to subsequently formed source/drain regions by subsequent etching processes used to form gate structures. The first inner spacers 90 may be formed by first depositing an inner spacer layer (not separately illustrated) by a deposition process, such as CVD, ALD, or the like. The inner spacer layer may comprise a low-dielectric constant (low-k) material having a k-value less than about 3.5, such as silicon nitride, silicon oxynitride, or the like. The inner spacer layer may then be etched to form the first inner spacers 90 by an anisotropic etching process, such as RIE, NBE, or the like.

Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54. Moreover, although the outer sidewalls of the first inner spacers 90 are illustrated as being straight in FIG. 11C, the outer sidewalls of the first inner spacers 90 may be concave or convex. FIG. 11D illustrates an embodiment in which sidewalls of the first nanostructures 52 are concave, outer sidewalls of the first inner spacers 90 are concave. FIG. 11E illustrates an embodiment in which the sidewalls of the first nanostructures 52 are concave, the outer sidewalls of the first inner spacers 90 are convex.

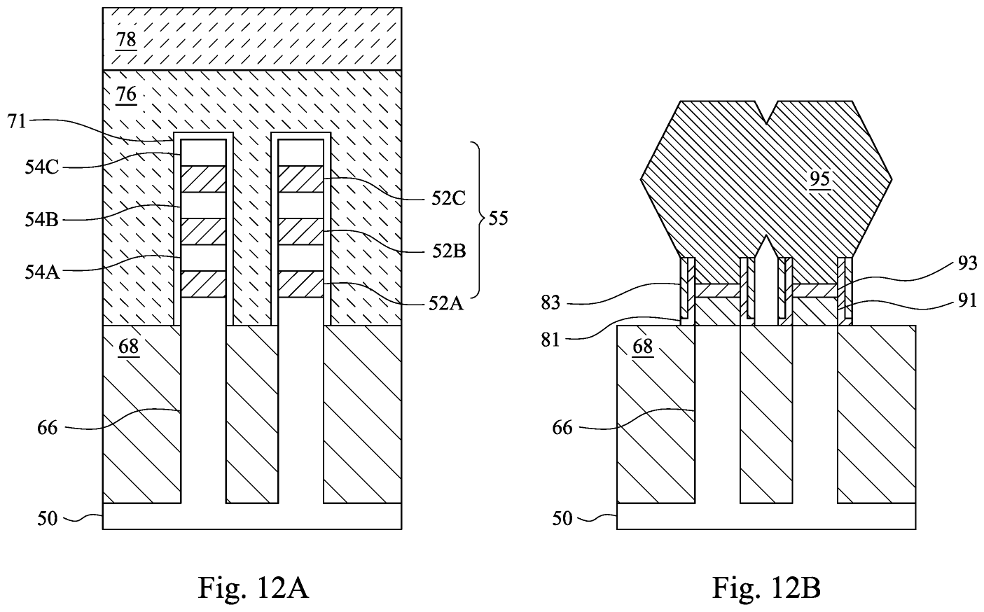

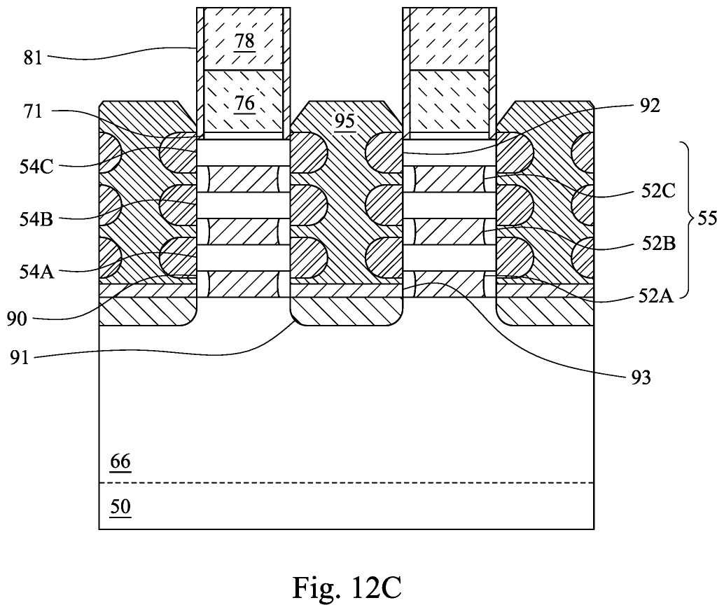

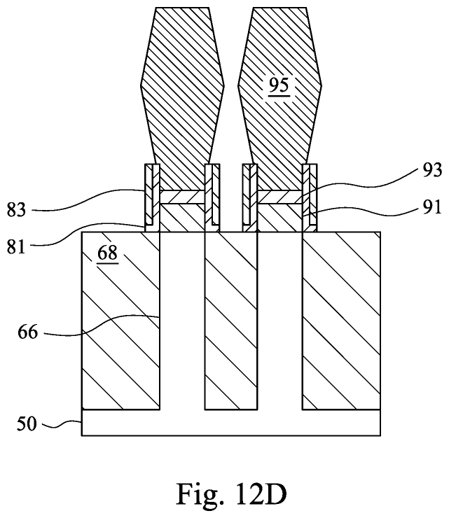

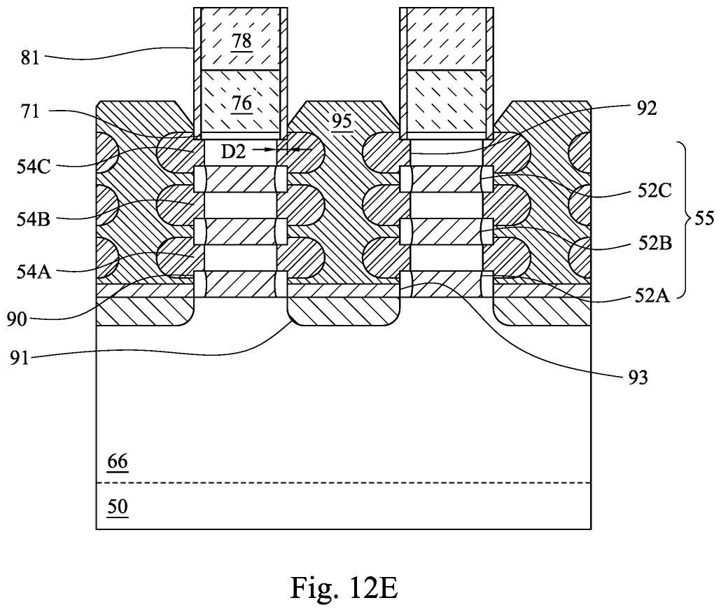

In FIGS. 12A through 12C, semiconductor layers 91, isolation layers 93, epitaxial source/drain regions 92, and sacrificial layers 95 are formed in the recesses 86 (shown in FIGS. 11B and 11C). The sacrificial layers 95 may also be referred to as material layers, and at least a portion of each sacrificial layer 95 may be removed in a subsequent etching process, as described in greater details below. The semiconductor layers 91 may be formed on the fins 66. The semiconductor layers 91 may be formed of a semiconductor material selected from the candidate semiconductor materials of the substrate 50, which may be formed by an epitaxial growth process such as VPE, MBE, or the like. The materials of the semiconductor layers 91 and the substrate 50 may be same or different. Timed epitaxial growth processes may be used to grow the semiconductor layers 91 to certain heights. The semiconductor layers 91 may be separated from the second nanostructures 54.

The isolation layers 93 are formed on the semiconductor layers 91. The isolation layers 93 may be in contact with the first inner spacers 90 on the first nanostructures 52A. Top surfaces of the isolation layers 93 may be disposed below the top surfaces of the first inner spacers 90 on the first nanostructures 52A (e.g., a bottom nanostructure of the first nanostructures 52). The isolation layers 93 may be separated from the second nanostructures 54. The isolation layers 93 may be formed by forming one or more dielectric material(s) over the semiconductor layers 91 by a deposition process, such as CVD, ALD, or the like. Acceptable dielectric materials may include silicon nitride, silicon oxynitride, silicon oxycarbonitride, silicon oxycarbide, silicon carbonitride, silicon oxide, aluminum oxide, hafnium oxide, or the like. FIG. 12C shows the isolation layers 93 as being above the top surfaces of the fins 66 as an example, the isolation layers 93 may be disposed at other locations, such as below the top surfaces of the fins 66.

The epitaxial source/drain regions 92 and the sacrificial layer 95 are formed in the n-type region 50N (e.g., the NMOS region) and in the p-type region 50P (e.g., the PMOS region) sequentially. For example, the p-type region 50P maybe masked when the epitaxial source/drain regions 92 and the sacrificial layer 95 are being formed in the n-type region 50N, and the n-type region 50N maybe masked when the epitaxial source/drain regions 92 and the sacrificial layer 95 are being formed in the p-type region 50P.

The epitaxial source/drain regions 92 are formed on the second nanostructures 54. The epitaxial source/drain regions 92 may be formed by an epitaxial growth process such as VPE, MBE, or the like. Process conditions, such as temperature, pressure, and processing time, may affect shapes of the epitaxial source/drain regions 92, as described in greater details below. In some embodiments, the epitaxial source/drain regions 92 may exert stress on the second nanostructures 54, thereby improving the performance of the subsequently formed semiconductor device. As illustrated in FIG. 12C, the epitaxial source/drain regions 92 may be formed on both sides of the second nanostructures 54 and the epitaxial source/drain regions 92 on each second nanostructure 54 are separated from the epitaxial source/drain regions 92 on another second nanostructure 54, which may increase contact areas between the epitaxial source/drain regions 92 and subsequently formed silicide layers, as described in greater details below. The epitaxial source/drain regions 92 may be in contact with the first spacers 81 and the first inner spacers 90. The first spacers 81 may separate the epitaxial source/drain regions 92 from the dummy gates 76 and the first inner spacers 90 may separate the epitaxial source/drain regions 92 from the first nanostructures 52 so that the epitaxial source/drain regions 92 do not short out with subsequently formed gate electrodes.

The epitaxial source/drain regions 92 in the p-type region 50P may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, germanium, germanium tin, or the like. In some embodiments, the epitaxial source/drain regions 92 in the p-type region 50P comprise silicon-germanium with a first germanium concentration in range from about 0% to about 80%, such as in range from about 40% to about 60%. The epitaxial source/drain regions 92 in the p-type region 50P may be formed using precursors, such as dichlorosilane, silane, disilane, germane, germanium tetrachloride, hydrochloric acid, chlorine, or the like. The epitaxial source/drain regions 92 in the p-type region 50P may be formed at a temperature in a range from about 520° C. to about 680° C. and under a pressure in a range from about 20 torr to about 80 torr.

The epitaxial source/drain regions 92 in the n-type region 50N may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, or the like. The epitaxial source/drain regions 92 in the p-type region 50P may be formed using precursors, such as dichlorosilane, silane, disilane, hydrochloric acid, chlorine, or the like. The epitaxial source/drain regions 92 in the n-type region 50N may be formed at a temperature in a range from about 600° C. to about 750° C. and under a pressure in a range from about 100 torr to about 300 torr.

The epitaxial source/drain regions 92 may be implanted with dopants by a similar implantation process as previously discussed with respect to forming LDD regions. In some embodiments, the dopants for the epitaxial source/drain regions 92 in the p-type region 50P comprise boron, gallium, or the like, with a concentration in a range from about 5×10¹⁹ atoms/cm³ to about 5×10²¹ atoms/cm³. In some embodiments, the dopants for the epitaxial source/drain regions 92 in the n-type region 50N comprise phosphorus, arsenic, antimony, or the like, with a concentration in a range from about 5×10¹⁹ atoms/cm³ to about 5×10²¹ atoms/cm³. In some embodiments, the epitaxial source/drain regions 92 may be in situ doped during growth, wherein diborane, boron trichloride, trimethylgallium, or the like may be used as a dopant precursor in the p-type region 50P, and phosphine, arsine, or the like may be used as a dopant precursor in the n-type region 50N.

The sacrificial layers 95 are then formed on the epitaxial source/drain regions 92. The sacrificial layers 95 may fill in the remaining portions of the recesses 86. As illustrated in FIG. 12C, the sacrificial layers 95 may be disposed between the neighboring epitaxial source/drain regions 92 as well as between the epitaxial source/drain regions 92 and the isolation layers 93. The sacrificial layers 95 may be in contact with the first spacers 81, the second spacers 83, and the first inner spacers 90. The sacrificial layers 95 may have top portions raised above respective top surfaces of the nanostructures 55 and the top portions of the sacrificial layers 95 may have facets as shown in FIGS. 12B and 12C.

The sacrificial layers 95 may comprise materials that have etch selectivity to the epitaxial source/drain regions 92. The sacrificial layers 95 in the p-type region 50P may include any acceptable material appropriate for p-type nano-FETs, such as silicon-germanium, germanium, germanium tin, or the like, formed by an epitaxial growth process such as VPE, MBE, or the like. In some embodiments, the sacrificial layers 95 in the p-type region 50P comprise silicon-germanium with a second germanium concentration in range from about 40% to about 80%, such as in range from about 50% to about 60%. The second germanium concentration of the sacrificial layers 95 may be higher than the first germanium concentration of the epitaxial source/drain regions 92, which may result in an etch selectivity between the epitaxial source/drain regions 92 and the sacrificial layers 95 in the p-type region 50P during a subsequent etching process, as described in greater details below. The sacrificial layers 95 in the p-type region 50P may be formed at a temperature in a range from about 520° C. to about 680° C. and under a pressure in a range from about 20 torr to about 80 torr. The sacrificial layers 95 in the n-type region 50N may include any acceptable material appropriate for n-type nano-FETs, such as silicon, silicon carbide, silicon phosphide, or the like, formed by an epitaxial growth process such as VPE, MBE, or the like. The sacrificial layers 95 in the n-type region 50N may be formed at a temperature in a range from about 600° C. to about 750° C. and under a pressure in a range from about 100 torr to about 300 torr.

The sacrificial layers 95 may be implanted with dopants by a similar implantation process as previously discussed with respect to forming LDD regions. In some embodiments, the dopants for the sacrificial layers 95 in the p-type region 50P comprise boron, gallium, or the like, with a concentration in a range from about 5×10¹⁹ atoms/cm³ to about 5×10²¹ atoms/cm³. In some embodiments, the dopants for the sacrificial layers 95 in the n-type region 50N comprise phosphorus, arsenic, antimony, or the like, with a concentration in a range from about 5×10¹⁹ atoms/cm³ to about 5×10²¹ atoms/cm³. In some embodiments, in the n-type region 50N, the dopant for the epitaxial source/drain regions 92 comprises arsenic and the dopant for the sacrificial layers 95 comprises phosphorus, which may result in an etch selectivity between the epitaxial source/drain regions 92 and the sacrificial layers 95 in the n-type region 50N during a subsequent etching process, as described in greater details below. In some embodiments, the sacrificial layers 95 may be in situ doped during growth.

As a result of the epitaxy processes used to form the sacrificial layers 95 in the n-type region 50N and the p-type region 50P, top portions of the sacrificial layers 95 may have facets which expand laterally outward beyond the first spacers 81 and the second spacers 83. In some embodiments, these facets cause the top portions of adjacent sacrificial layers 95 to merge as illustrated by FIG. 12B. In some embodiments, the top portions of the adjacent sacrificial layers 95 remain separated after the epitaxy processes are completed as illustrated by FIG. 12D. The first spacers 81 and the second spacers 83 may be on a top surface of the STI regions 68 and block the lateral expansion of the bottom portions of the sacrificial layers 95.

In some embodiments, the sacrificial layers 95 comprise a dielectric material, such as silicon oxycarbonitride or the like. In some embodiments, the silicon oxycarbonitride in the sacrificial layers 95 comprises 20% to 80% oxygen, 0% to 20% carbon, and 0% to 40% nitrogen. In such embodiments, the sacrificial layers 95 are formed by a deposition process such as by CVD, ALD, or the like, and excess dielectric material may be removed after the deposition process. Unlike the embodiments shown in FIGS. 12B and 12C, the sacrificial layers 95 comprising the dielectric material may be free of facets (not separately illustrated).

In some embodiments, the second nanostructures 54 may be recessed on both sides by a suitable etching process before the epitaxial source/drain regions 92 are formed. As a result, the epitaxial source/drain regions 92 may extend into the recesses and beyond the outer sidewalls of the first inner spacers 90 towards the second nanostructures 54 by a distance D2, as illustrated by FIG. 12E. The distance D2 may be in a range between about 1 nm and about 5 nm. The distance D2 may be referred to as a push-in distance of the epitaxial source/drain regions 92.

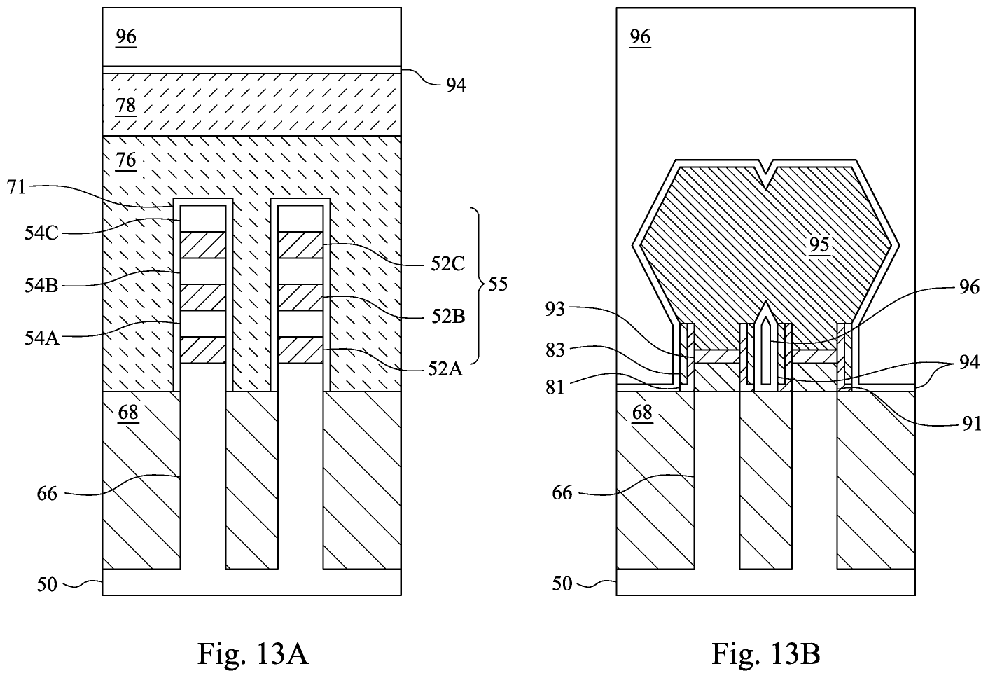

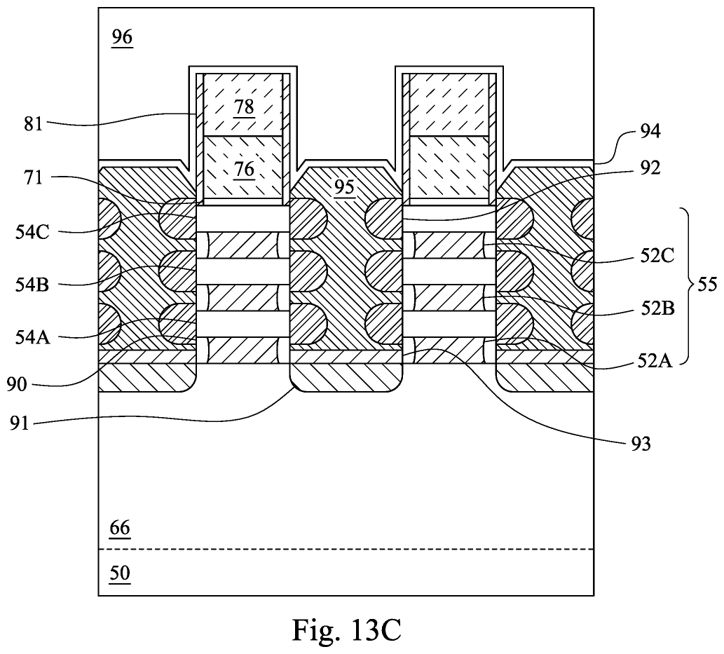

In FIGS. 13A through 13C, a first interlayer dielectric (ILD) 96 is deposited over the structure illustrated in FIGS. 12A through 12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the sacrificial layers 95, the masks 78, and the first spacers 81. The CESL 94 may comprise a dielectric material, such as, silicon nitride, silicon oxide, silicon oxynitride, or the like, having a different etch rate than the material of the overlying first ILD 96.

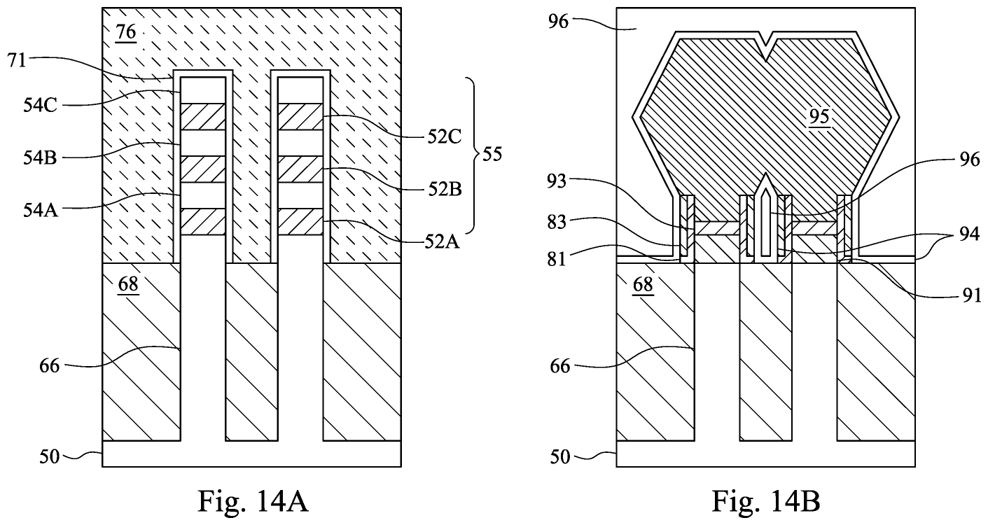

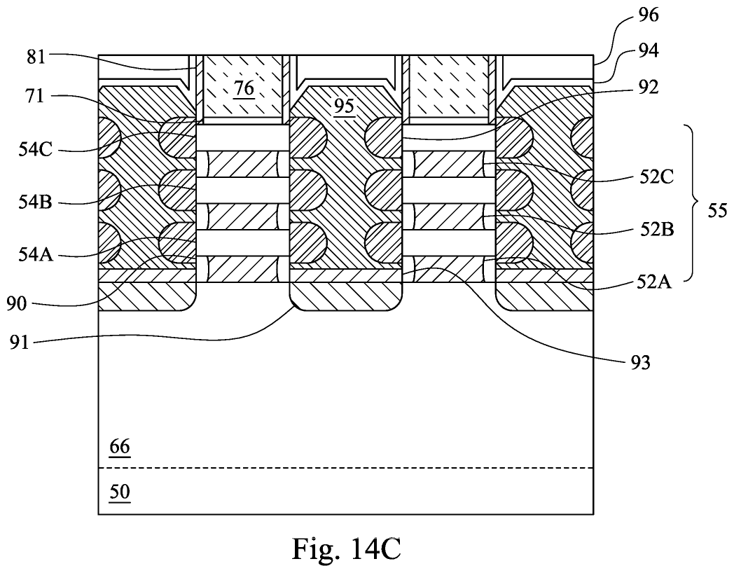

In FIGS. 14A through 14C, a planarization process, such as a CMP process, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 may be substantially co-planar or level. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

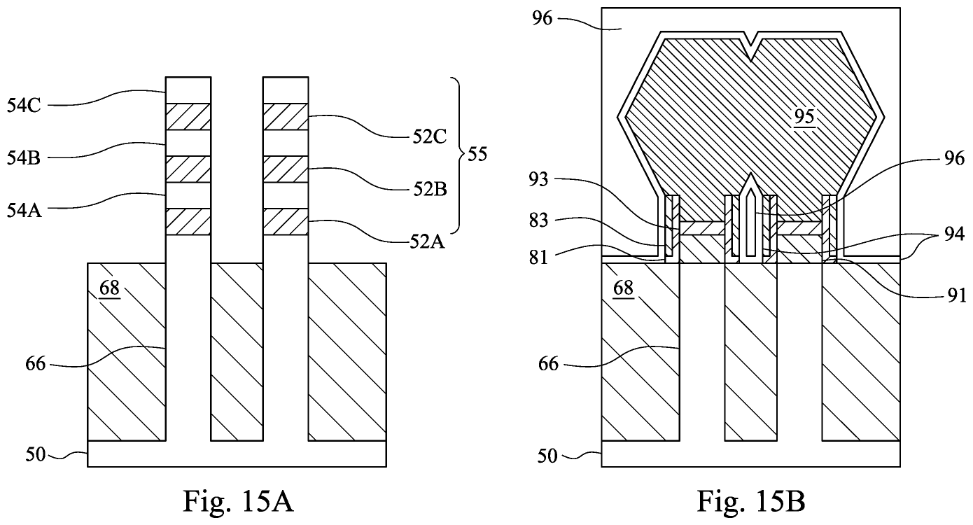

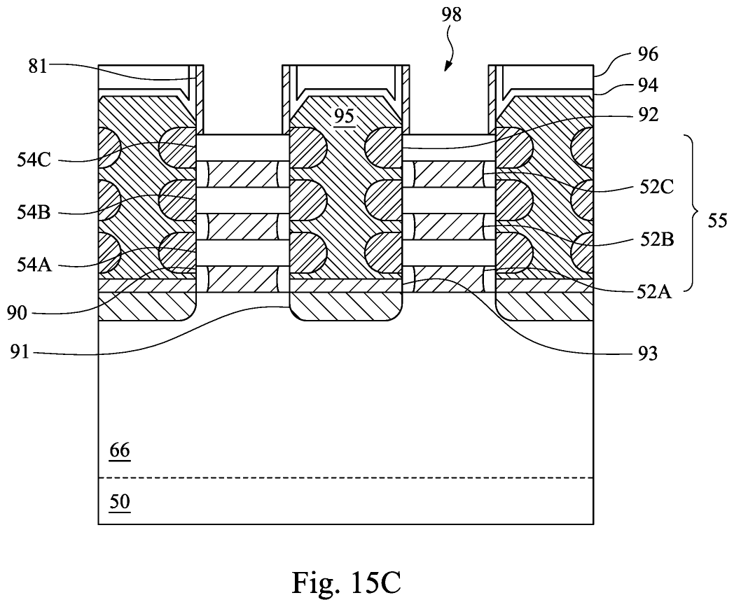

In FIGS. 15A through 15C, the dummy gates 76, and the masks 78 if present, are removed in one or more etching steps, so that recesses 98 are formed. Portions of the dummy gate dielectrics 71 in the recesses 98 are also be removed. In some embodiments, the dummy gates 76 and the dummy gate dielectrics 71 are removed by an anisotropic dry etch process. For example, the etching process may include a dry etch process using reaction gas(es) that selectively etch the dummy gates 76 at a faster rate than the first ILD 96 or the first spacers 81. Each of the recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

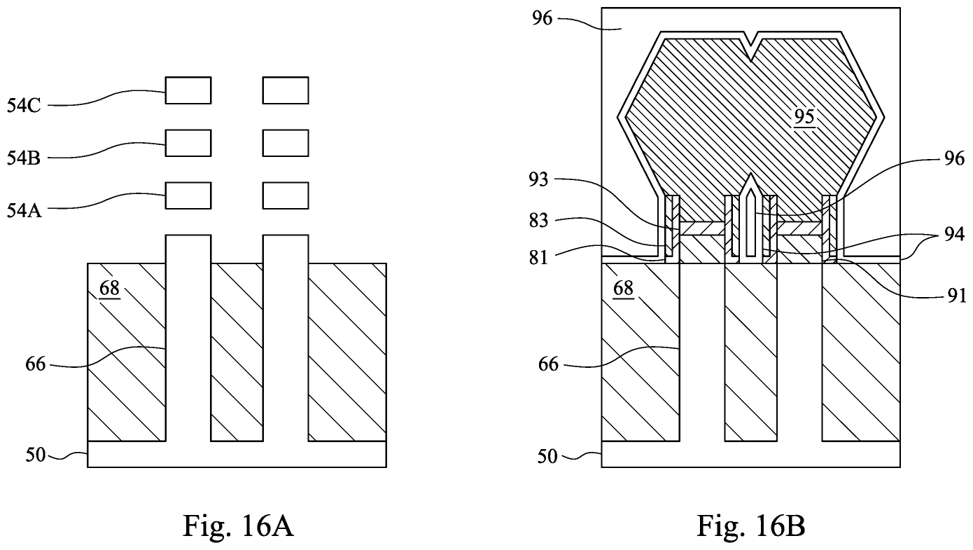

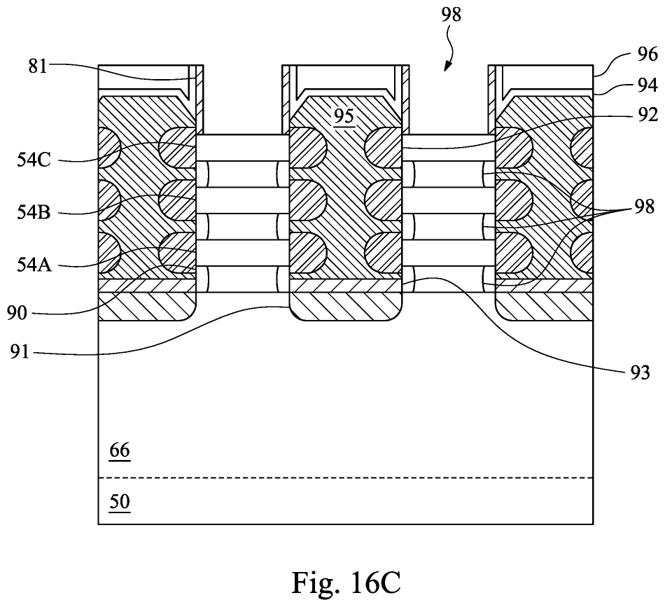

In FIGS. 16A through 16C, the first nanostructures 52 are removed extending the recesses 98. The first nanostructures 52 may be removed by performing an isotropic etching process such as wet etching or the like using etchants which are selective to the materials of the first nanostructures 52, while the second nanostructures 54, the substrate 50, the STI regions 68 remain relatively un-etched as compared to the first nanostructures 52. In embodiments in which the first nanostructures 52 comprise silicon-germanium or the like, and the second nanostructures 54 comprise silicon, silicon carbide, or the like, tetramethylammonium hydroxide (TMAH), ammonium hydroxide (NH₄OH), or the like may be used to remove the first nanostructures 52.

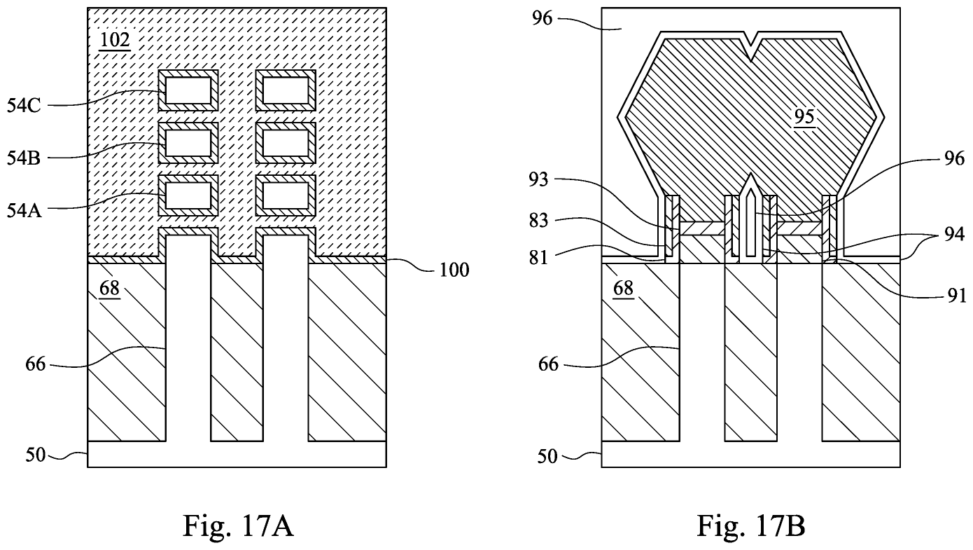

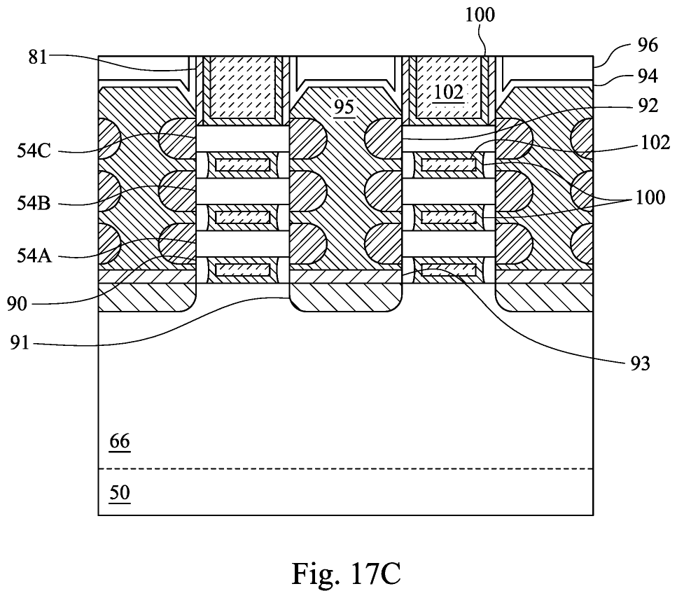

In FIGS. 17A through 17C, gate dielectric layers 100 and gate electrodes 102 are formed for replacement gates. The gate dielectric layers 100 are deposited conformally in the recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the first spacers 81, and the STI regions 68 and on sidewalls of the first spacers 81 and the first inner spacers 90.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the recesses 98, a planarization process, such as a CMP process, may be performed to remove the excess portions of the gate dielectric layers 100 and the material of the gate electrodes 102, which excess portions are over the top surface of the first ILD 96. After the planarization process, surfaces of the first ILD 96, the gate electrodes 102, and the gate dielectric layers 100 may be substantially co-planar or level. The remaining portions of material of the gate electrodes 102 and the gate dielectric layers 100 thus form replacement gate structures of the resulting nano-FETs. The gate electrodes 102 and the gate dielectric layers 100 may be collectively referred to as gate structures.

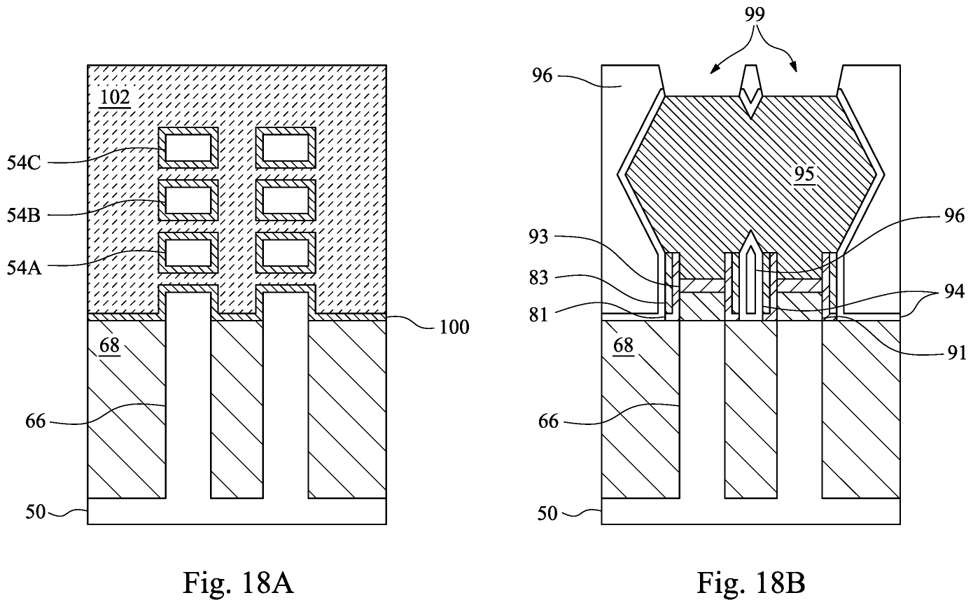

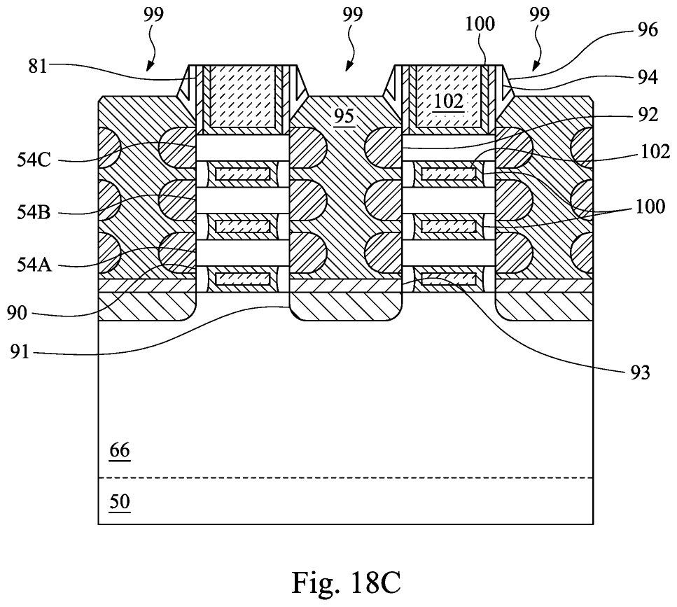

In FIGS. 18A through 18C, recesses 99 are formed through the first ILD 96 and the CESL 94 to expose top surfaces of the sacrificial layers 95. The recesses 99 may be formed by one or more etching processes, such as RIE, NBE, or the like. In some embodiments, the recesses 99 may be formed by etching through the first ILD 96 using a first etching process and etching through the CESL 94 using a second etching process. A mask, such as patterned photoresist, may be formed before the etching processes and removed after the etching processes.

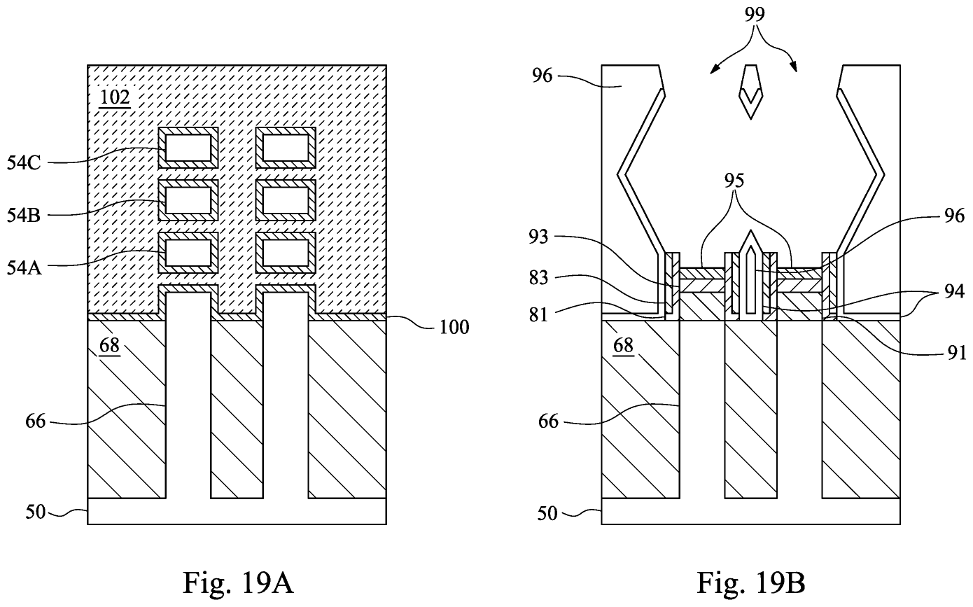

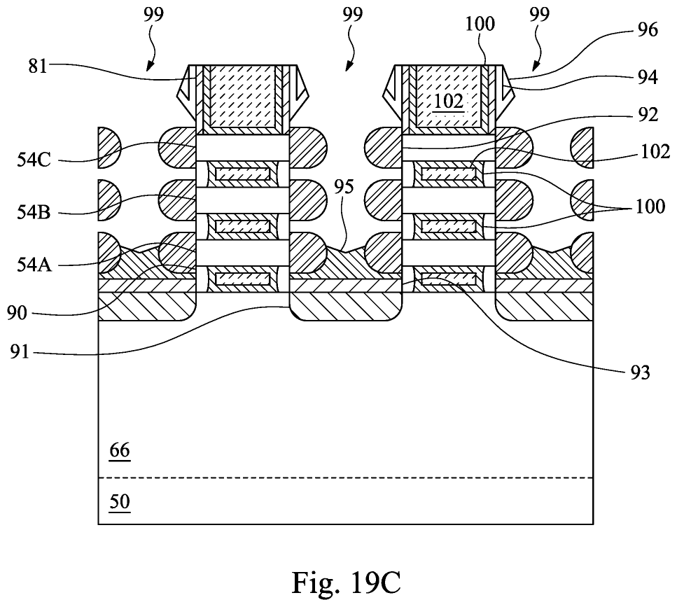

In FIGS. 19A through 19C, the recesses 99 are expanded by removing at least a portion of the sacrificial layer 95 to expose surfaces of at least some of the epitaxial source/drain regions 92. Sidewalls of at least some of the first spacers 81 and the first inner spacers 90 may also be exposed. In some embodiments, a portion of the sacrificial layer 95 remains along a bottom of the recesses 99. The remaining sacrificial layer 95 may have a concaved top surface and may be on a top surface of the corresponding isolation layer 93 and surfaces of some of the corresponding the epitaxial source/drain regions 92 adjacent the isolation layer 93. The sacrificial layer 95 may be removed by one or more etching processes, such as dry etching processes, or the like. After the etching processes, the epitaxial source/drain regions 92 may be substantially intact.

The sacrificial layer 95 may be removed in the n-type region 50N and in the p-type region 50P sequentially. For example, the p-type region 50P maybe masked when the sacrificial layer 95 is being removed in the n-type region 50N, and the n-type region 50N maybe masked when the sacrificial layer 95 is being removed in the p-type region 50P. Etchants used to remove the sacrificial layer 95 in the p-type region 50P may be different from etchants used to remove the sacrificial layer 95 in the n-type region 50N. During the etching processes, the etching rate of the sacrificial layer 95 may be larger than the epitaxial source/drain regions 92. In the p-type region 50P, such etch selectivity may be the result of the second germanium concentration of the sacrificial layers 95 being higher than the first germanium concentration of the epitaxial source/drain regions 92. In the n-type region 50N, such etch selectivity may be the result of the dopants in the epitaxial source/drain regions 92 (e.g., arsenic) being different from the dopants in the sacrificial layers 95 (e.g., phosphorus).

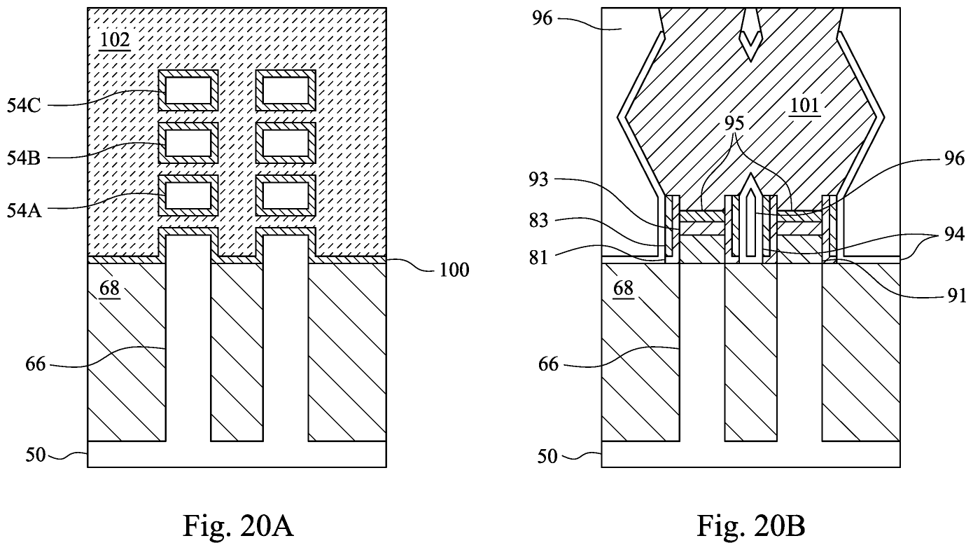

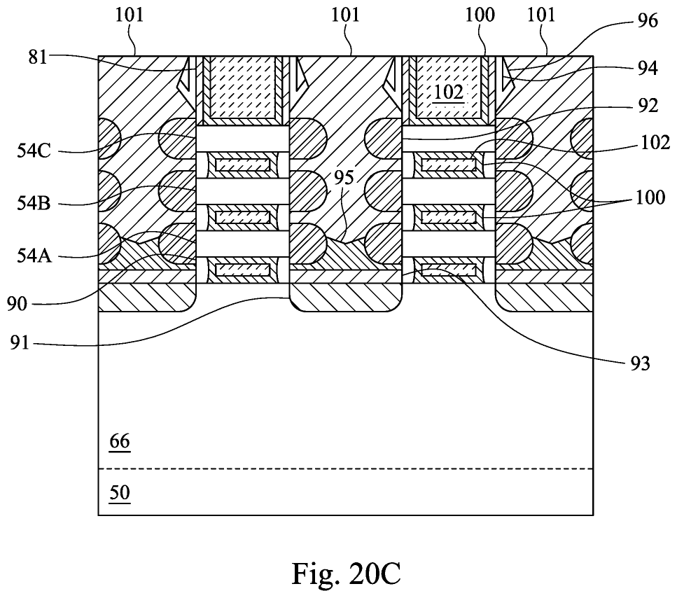

In FIGS. 20A through 20C, metal layers 101 are formed in the recesses 99. The metal layers 101 may fill up the recesses 99. The metal layers 101 may comprise titanium, nickel, cobalt, platinum, or the like and may be formed by plating, PVD, or the like. A planarization process, such as a CMP process, may be performed to remove excess material from surfaces of the first ILD 96, the CESL 94, and the gate electrodes 102 after the metal layers 101 are formed. After the planarization process, surfaces of the first ILD 96, the CESL 94, the gate electrodes 102, and the metal layers 101 may be substantially co-planar or level.

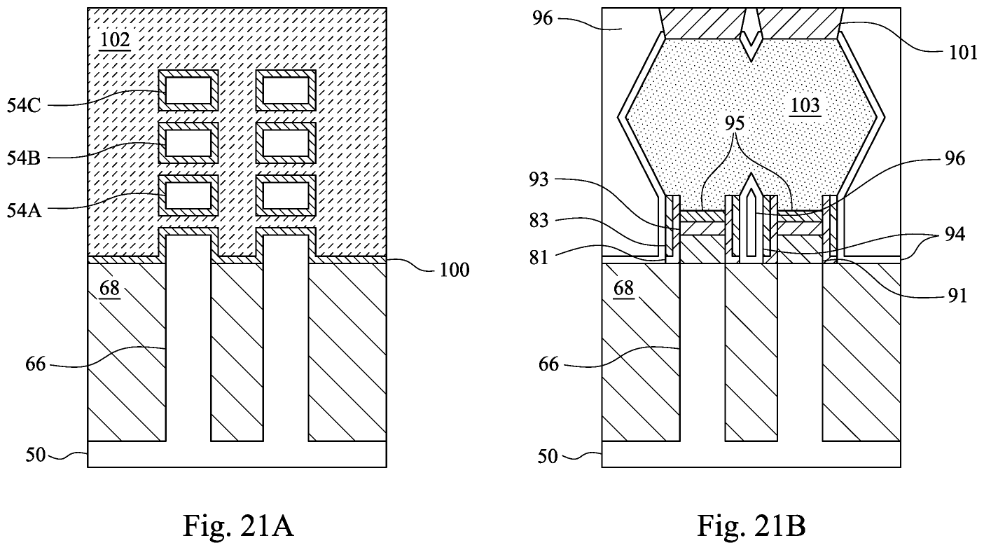

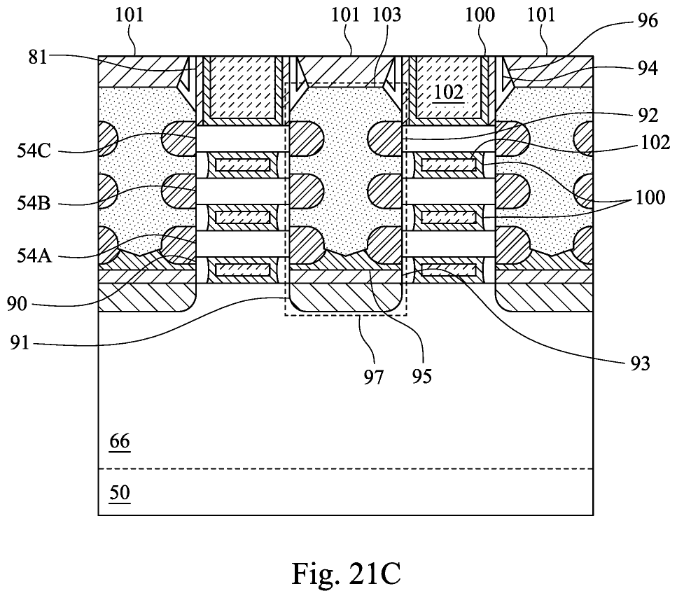

In FIGS. 21A through 21C, silicide layers 103 are formed on the epitaxial source/drain regions 92. The silicide layers 103 may electrically connect the epitaxial source/drain regions 92 to the remaining metal layers 101. In some embodiments, the silicide layers 103 are also formed on the remaining portions of the sacrificial layers 95. In some embodiments, the silicide layers 103 extend continuously between neighboring epitaxial source/drain regions 92 and completely fill up gaps between the between neighboring epitaxial source/drain regions 92 on the same stack of the second nanostructures 54 or on neighboring stacks of the second nanostructures 54. Due to the shapes of the epitaxial source/drain regions 92 and the silicide layers 103, the contact areas between the epitaxial source/drain regions 92 and the silicide layers 103 may be increased, which may result in reduced electrical resistance between the epitaxial source/drain regions 92 and the silicide layers 103, thereby reducing electrical resistance between the epitaxial source/drain regions 92 and subsequently formed source/drain contacts on the remaining metal layers 101, as described in greater details below.

The silicide layers 103 may be formed by performing a thermal annealing process to induce reactions between the metal layers 101 and the epitaxial source/drain regions 92. The thermal annealing process may further induce reactions between the metal layers 101 and the sacrificial layers 95 in embodiments in which the sacrificial layers 95 comprises a semiconductor material. As a result, portions of the metal layers 101, the epitaxial source/drain regions 92, and the sacrificial layers 95 may be turned into the silicide layers 103. The portions of the epitaxial source/drain regions 92 that are in contact with the sacrificial layers 95 may remain intact after the thermal annealing process. The thermal annealing process may be performed at a temperature in a range between about 450° C. to about 850° C. for a time period in a range between about 1 second to about 3 minutes. Between two neighboring stacks of the second nanostructures 54, the corresponding semiconductor layer 91, the corresponding isolation layer 93, the corresponding epitaxial source/drain regions 92, the corresponding sacrificial layer 95, and the corresponding silicide layer 103 may be collectively referred to as an area 97.

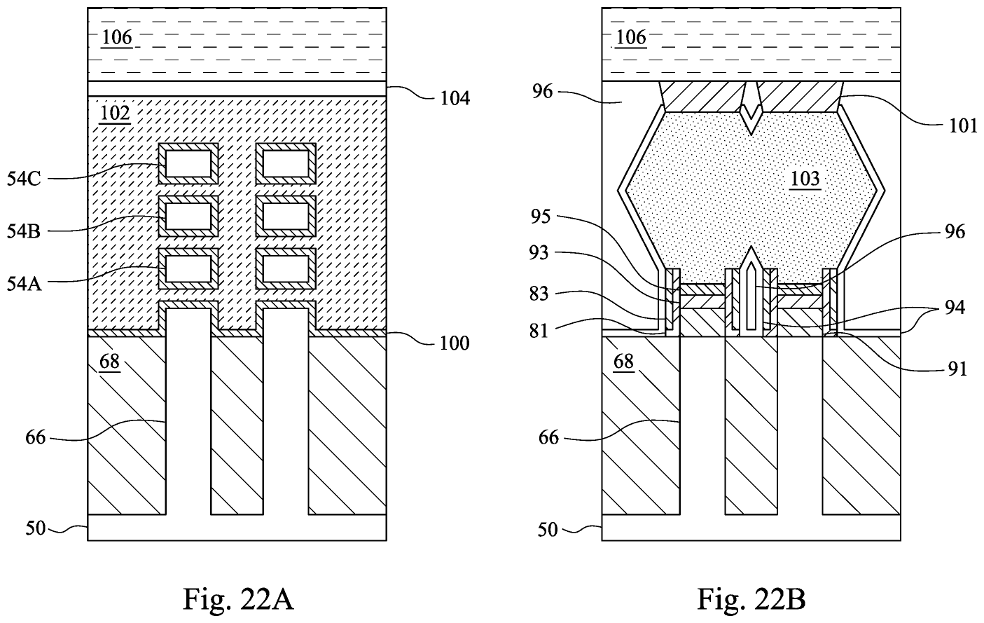

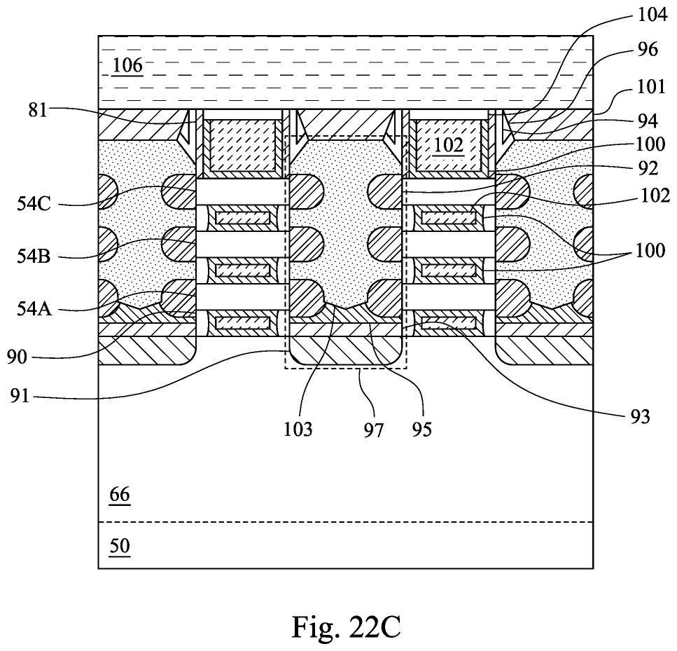

In FIGS. 22A through 22C, the gate structures (including the gate dielectric layers 100 and the corresponding overlying gate electrodes 102) are recessed, so that recess are formed directly over the gate structures and between opposing portions of first spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96. Subsequently formed gate contacts may penetrate through the gate masks 104 to contact the top surfaces of the recessed gate electrodes 102.

As further illustrated by FIGS. 22A through 22C, a second ILD 106 is deposited over the first ILD 96 and over the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

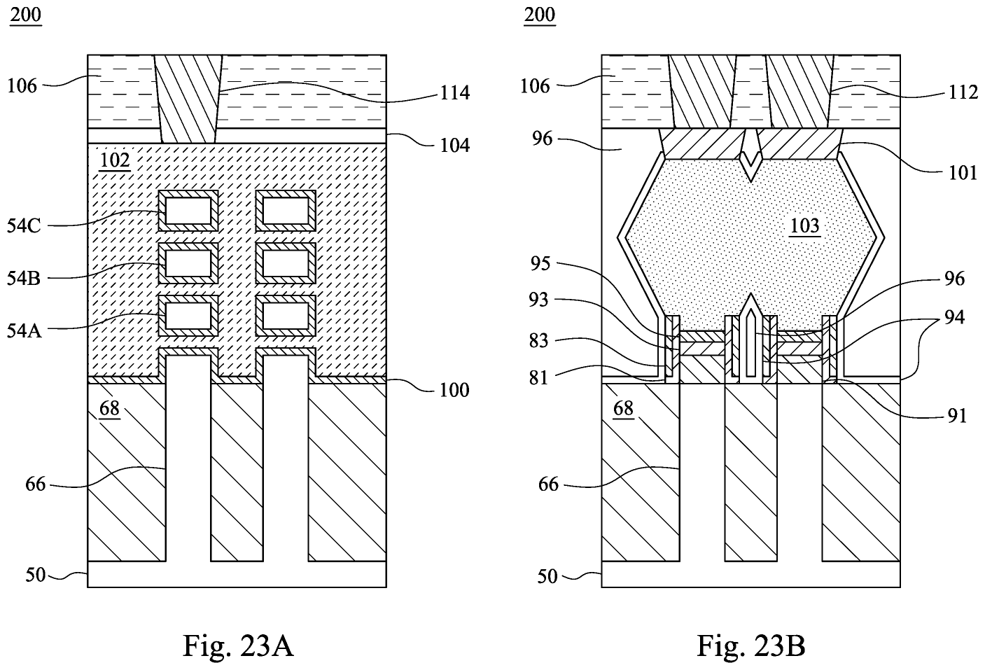

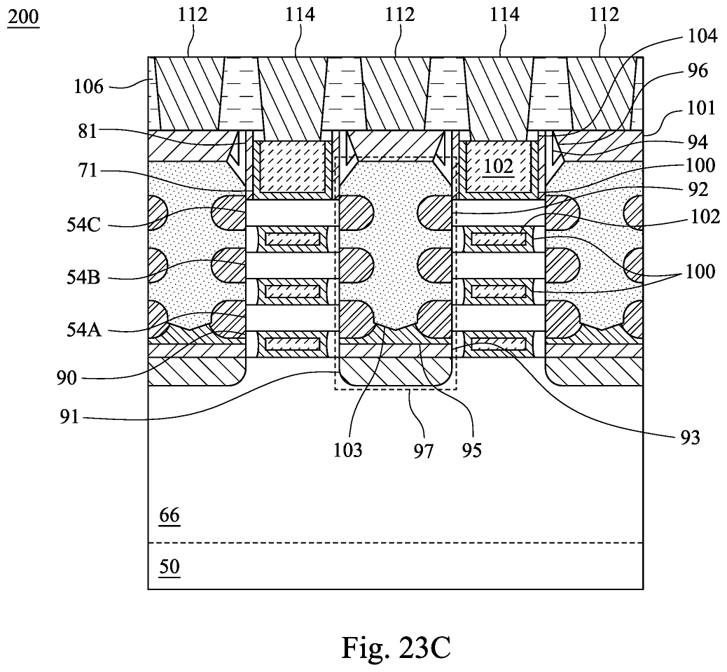

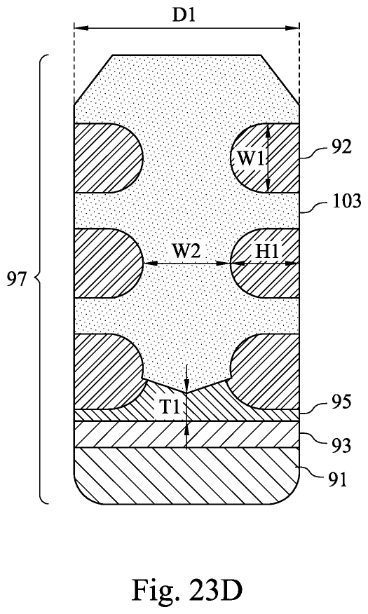

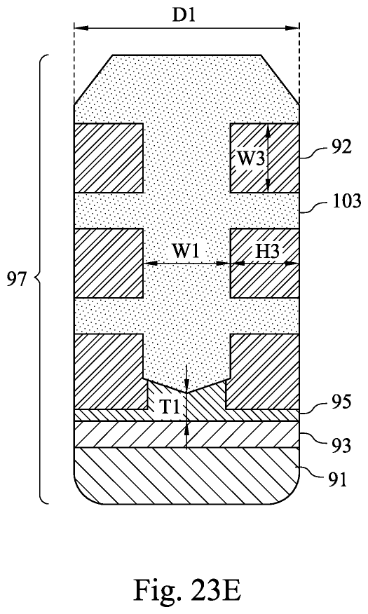

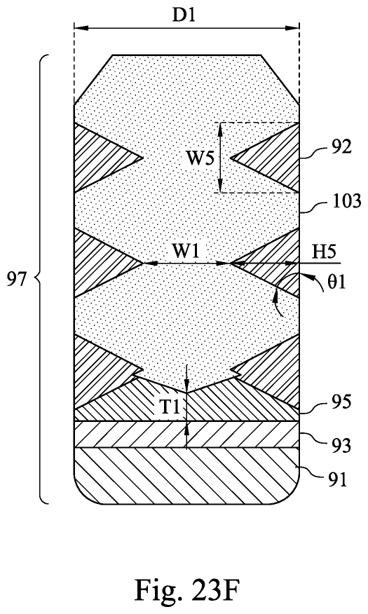

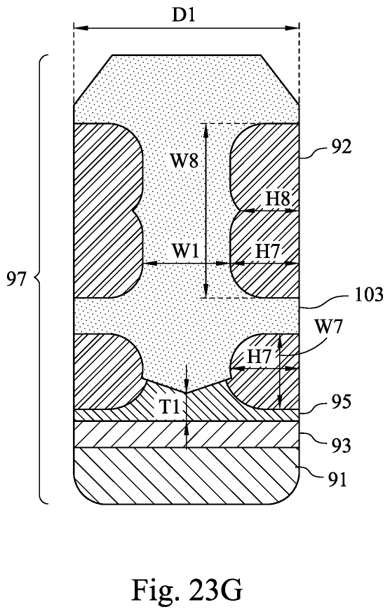

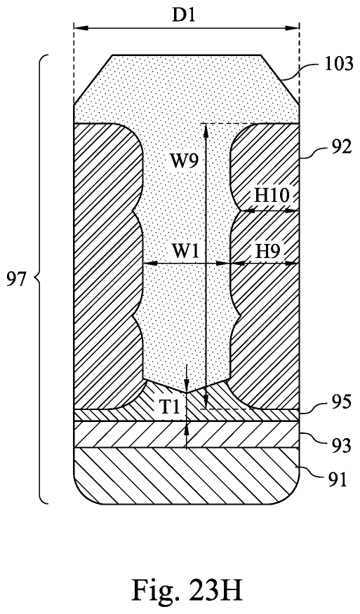

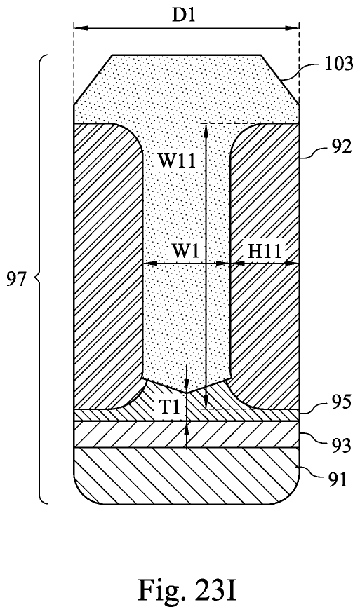

In FIGS. 23A through 23C, source/drain contacts 112 are formed through the second ILD 106 to contact the metal layer 101 and gate contacts 114 are formed through the second ILD 106 and the gate masks 104 to contact the gate electrodes 102. The structure shown in FIGS. 23A through 23C may be referred to a semiconductor device 200. The source/drain contacts 112 may be electrically connected to the epitaxial source/drain regions 92 and the gate contacts 114 may be electrically connected to the gate electrodes 102. The source/drain contacts 112 and the gate contacts 114 may be also referred to as conductive contacts. Due to reduced electrical resistance between the epitaxial source/drain regions 92 and the silicide layers 103 described above with respect to FIGS. 21A through 21C, the electrical resistance between the epitaxial source/drain regions 92 and the source/drain contacts 112 may be also reduced, thereby improving the performance of the semiconductor device 200.

The source/drain contacts 112 and the gate contacts 114 may each comprise one or more layers, such as barrier layers, diffusion layers, and fill materials. The barrier layer may include titanium, titanium nitride, tantalum, tantalum nitride, or the like. The conductive material may be copper, a copper alloy, silver, gold, tungsten, cobalt, aluminum, nickel, ruthenium, molybdenum, or the like. The source/drain contacts 112 and the gate contacts 114 may be formed by plating, PVD, or the like. A planarization process, such as a CMP process, may be performed to remove excess material from surfaces of the second ILD 106 after the source/drain contacts 112 and the gate contacts 114 are formed. After the planarization process, surfaces of source/drain contacts 112, the gate contacts 114, and the second ILD 106 may be substantially co-planar or level.

FIG. 23D shows an enlarged view of the area 97 of the semiconductor device 200 shown in FIG. 23C. In the embodiments illustrated in FIG. 23D, the epitaxial source/drain regions 92 may have a shape of an arch, which may be in contact with corresponding ones of the second nanostructure 54 (shown in FIG. 23C). The epitaxial source/drain regions 92 may have a height Hi from the second nanostructure 54 in a range from about 1 nm to about 8 nm and a width W1 in a range from about 1 nm to about 30 nm. The silicide layer 103 may have a width W2 which may correspond to a distance between two opposing epitaxial source/drain regions 92 on neighboring stacks of the second nanostructures 54. The width W2 may be in a range from about 3 nm to about 20 nm. The sacrificial layer 95 may have a thickness T1 in a range from about 1 nm to about 60 nm. The thickness T1 may be a smallest thickness of the sacrificial layer 95. A width of the area 97 may correspond to the width D1 of the recess 86 described with respect to FIG. 9C.

FIG. 23E shows an example of the area 97 similar to the one shown in FIG. 23D, wherein like reference numerals refer to like features. In the embodiments illustrated in FIG. 23E, the epitaxial source/drain regions 92 may have a shape of a rectangle, which may be in contact with one second nanostructure 54 (shown in FIG. 23C). The epitaxial source/drain regions 92 may have a height H3 in a range from about 1 nm to about 8 nm and a width W3 in a range from about 1 nm to about 30 nm. The silicide layer 103 may have the width W1 which may correspond to the distance between two opposing epitaxial source/drain regions 92 on neighboring stacks of the second nanostructures 54.

FIG. 23F shows an example of the area 97 similar to the one shown in FIG. 23D, wherein like reference numerals refer to like features. In the embodiments illustrated in FIG. 23F, the epitaxial source/drain regions 92 may have a shape of a triangle, which may be in contact with one second nanostructure 54 (shown in FIG. 23C). The epitaxial source/drain regions 92 may have a height H5 in a range from about 1 nm to about 8 nm, a width W5 in a range from about 1 nm to about 30 nm, and an internal angle θ1 in a range from about 20° to about 60°, such as 35° and 54°. The silicide layer 103 may have the width W1 which may correspond to the distance between two opposing epitaxial source/drain regions 92 on neighboring stacks of the second nanostructures 54.

FIG. 23G shows an example of the area 97 similar to the one shown in FIG. 23D, wherein like reference numerals refer to like features. In the embodiments illustrated in FIG. 23G, some of the epitaxial source/drain regions 92 may have a shape of an arch, which may be in contact with one second nanostructure 54 (shown in FIG. 23C). Such epitaxial source/drain regions 92 may have with a height H7 in a range from about 1 nm to about 8 nm and a width W7 in a range from about 1 nm to about 30 nm. Some of the epitaxial source/drain regions 92 may have a shape of a merged arch with a wavy surface, which may be in contact with two second nanostructures 54 and extend continuously from one second nanostructure 54 to the other second nanostructure 54. Such epitaxial source/drain regions 92 may have the height H7 in a range from about 1 nm to about 8 nm, a height H8 smaller than the height H7, and a width W8 in a range from about 1 nm to about 60 nm. The height H7 may be a largest height of the corresponding epitaxial source/drain regions 92 and the height H8 may be a smallest height of the corresponding epitaxial source/drain regions 92. The silicide layer 103 may have the width W1 which may correspond to the distance between two opposing epitaxial source/drain regions 92 on neighboring stacks of the second nanostructures 54.

FIG. 23H shows an example of the area 97 similar to the one shown in FIG. 23D, wherein like reference numerals refer to like features. In the embodiments illustrated in FIG. 23H, the epitaxial source/drain regions 92 may have a shape of a merged arch with a wavy surface, which may be in contact with three second nanostructures 54 (shown in FIG. 23C) and extend continuously from among the three second nanostructure 54. The epitaxial source/drain regions 92 may have a height H9 in a range from about 1 nm to about 8 nm, a height H10 smaller than the height H9, and a width W9 in a range from about 1 nm to about 90 nm. The height H9 may be a largest height of the epitaxial source/drain regions 92 and the height H10 may be a smallest height of the epitaxial source/drain regions 92. The silicide layer 103 may have the width W1 which may correspond to the distance between two opposing epitaxial source/drain regions 92 on neighboring stacks of the second nanostructures 54.

FIG. 23I shows an example of the area 97 similar to the one shown in FIG. 23D, wherein like reference numerals refer to like features. In the embodiments illustrated in FIG. 23I, the epitaxial source/drain regions 92 may have a shape of an arch, which may be in contact with three second nanostructures 54 (shown in FIG. 23C) and extend continuously from among the three second nanostructure 54. The epitaxial source/drain regions 92 may have a height Hi in a range from about 1 nm to about 8 nm and a width W11 in a range from about 1 nm to about 90 nm. The silicide layer 103 may have the width W1 which may correspond to the distance between two opposing epitaxial source/drain regions 92 on neighboring stacks of the second nanostructures 54.

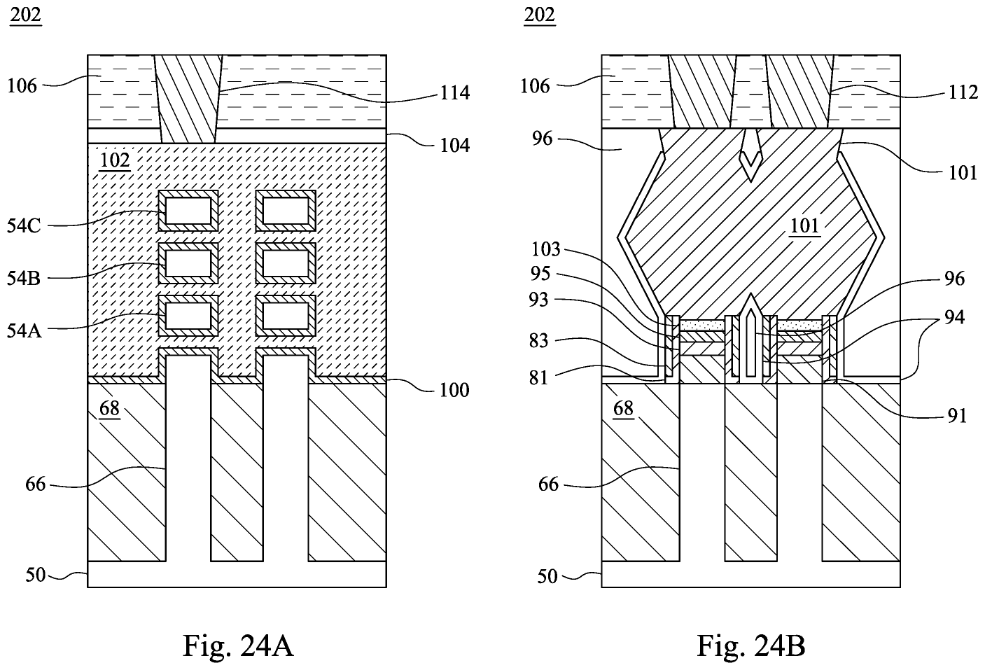

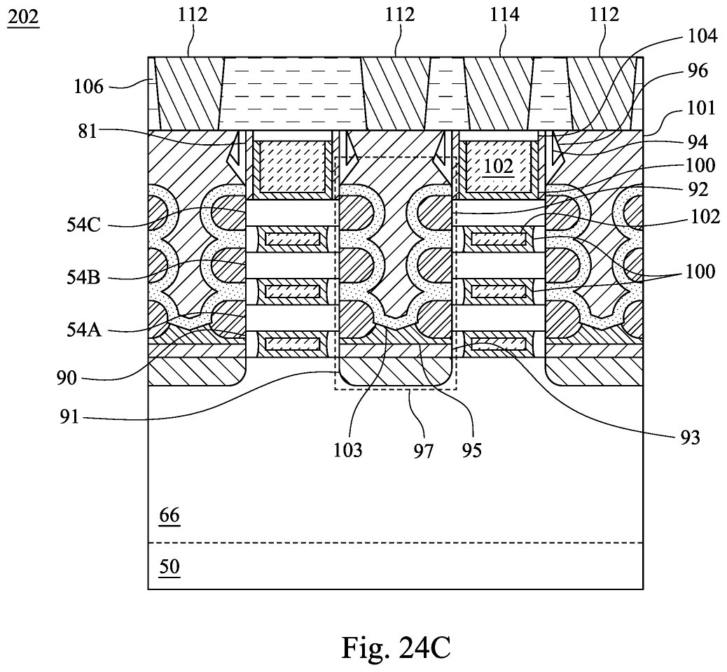

FIGS. 24A, 24B, and 24C show different cross-sections of a semiconductor device 202 similar to the cross-sections of the semiconductor device 200 shown in FIGS. 23A, 23B, and 23C, respectively, in accordance with some embodiments, wherein like reference numerals refer to like features. In the embodiments shown in FIGS. 24A, 24B, and 24C, in at least one of the areas 97, a portion of the metal layer 101 remains between the opposing epitaxial source/drain regions 92 on neighboring stacks of the second nanostructures 54. The silicide layer 103 may extend continuously on the surfaces of the epitaxial source/drain regions 92 and the sacrificial layer 95.

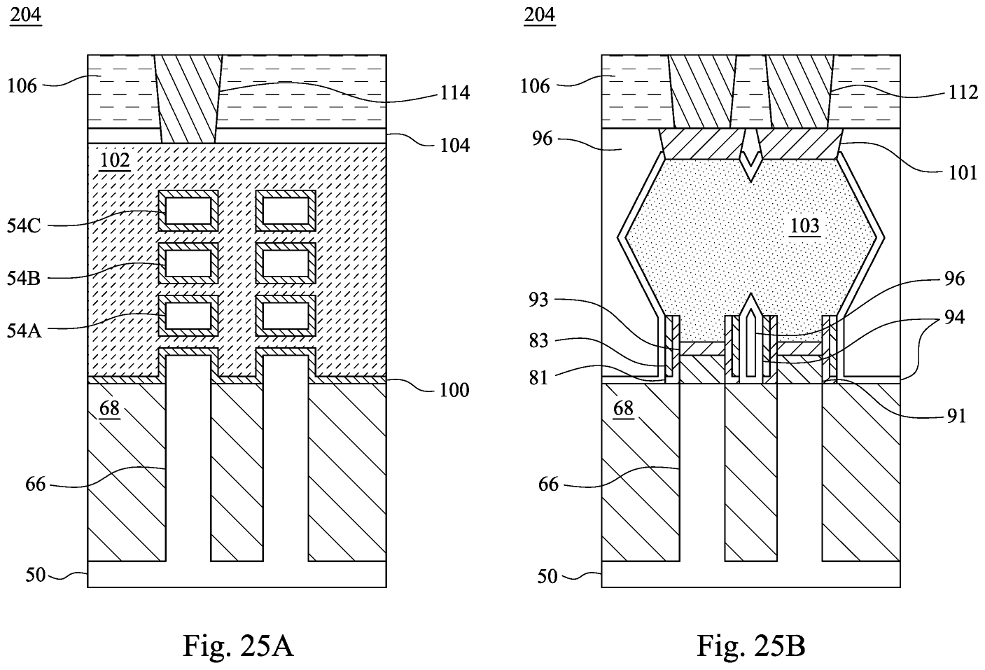

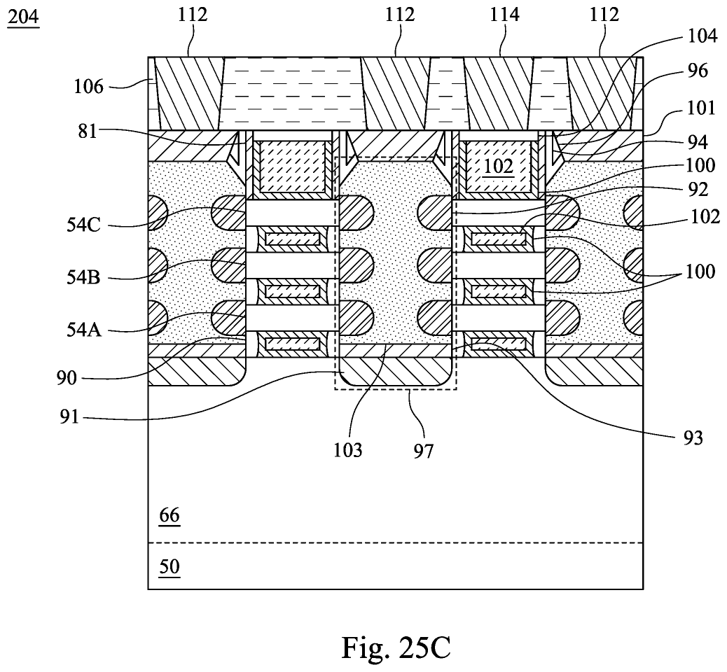

FIGS. 25A, 25B, and 25C show different cross-sections of a semiconductor device 204 similar to the cross-sections of the semiconductor device 200 shown in FIGS. 23A, 23B, and 23C, respectively, in accordance with some embodiments, wherein like reference numerals refer to like features. In the embodiments shown in FIGS. 25A, 25B, and 25C, in at least one of the areas 97, the sacrificial layer 95 is completely removed. The silicide layer 103 may be in contact with the top surface of the isolation layer 93 and may fill in the gaps between the epitaxial source/drain regions 92 and the isolation layer 93. Due to the shapes the silicide layers 103, the contact areas between the epitaxial source/drain regions 92 and the silicide layers 103 in the semiconductor device 204 may be further increased compared to the semiconductor device 200, which may result in further reduced electrical resistance between the epitaxial source/drain regions 92 and the source/drain contacts 112, thereby further improving the performance of the semiconductor device 204.

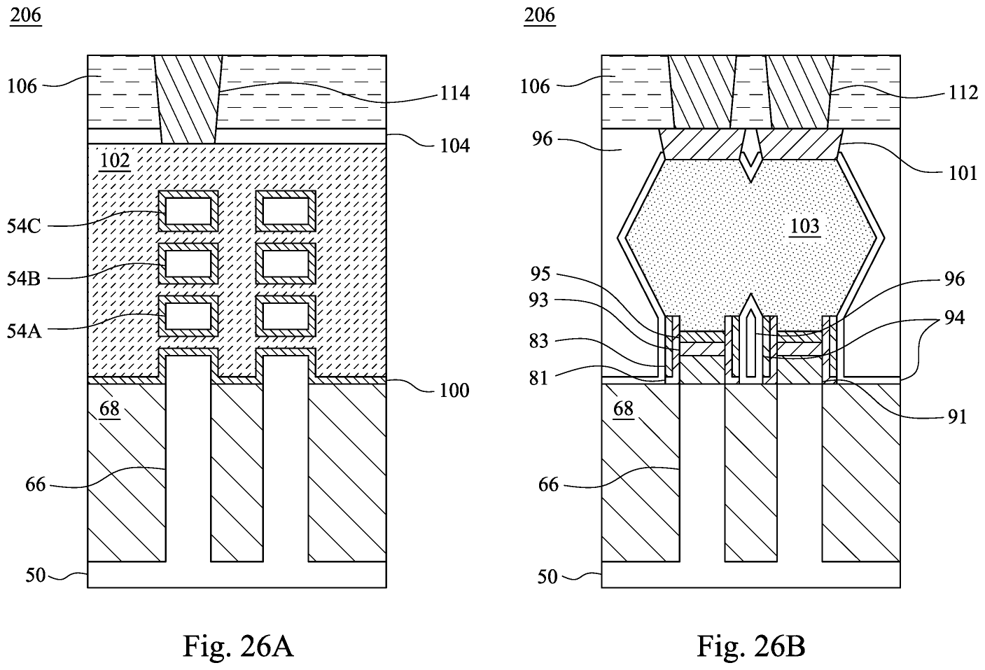

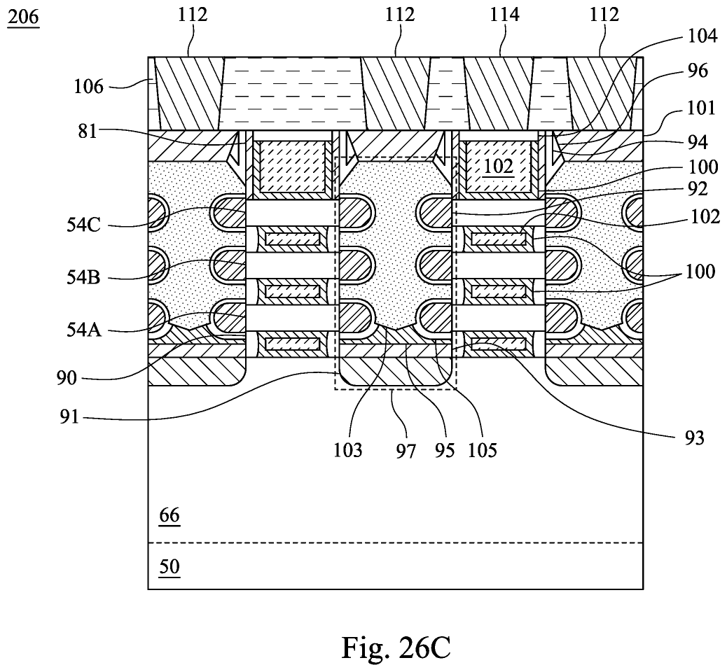

FIGS. 26A, 26B, and 26C show different cross-sections of a semiconductor device 206 similar to the cross-sections of the semiconductor device 200 shown in FIGS. 23A, 23B, and 23C, respectively, in accordance with some embodiments, wherein like reference numerals refer to like features. In the embodiments shown in FIGS. 26A, 26B, and 26C, an etch stop layer 105 is formed on each epitaxial source/drain region 92 before forming the sacrificial layers 95. The etch stop layers 105 may separate the epitaxial source/drain regions 92 from the sacrificial layers 95 and the silicide layers 103. During the thermal annealing process, the metal layers 101 and the etch stop layers 105 may react. As a result, portions of the etch stop layers 105 that are in contact with the metal layers 101 may be turned into the silicide layers 103. The portions of the etch stop layers 105 that are in contact with the sacrificial layers 95 may remain intact after the thermal annealing process. The silicide layers 103 may be electrically connected to the epitaxial source/drain regions 92 through the etch stop layers 105. The etch stop layer 105 may be formed by a similar process and under similar conditions as the epitaxial source/drain regions 92. An oxidation treatment may be performed on the etch stop layers 105 to create an oxide layer (not separately illustrated) with a thickness in range between about 0.5 nm to about 2 nm. The oxide layer may improve an etch selectivity between the etch stop layers 105 and the sacrificial layers 95 during the etching process, as described in greater details below. The oxide layer may be removed before forming the metal layers 101.

The etch stop layers 105 in the p-type region 50P may comprise silicon-germanium, germanium, germanium tin, silicon, or the like. In some embodiments, the etch stop layers 105 in the p-type region 50P comprise silicon-germanium with a third germanium concentration in range from about 0% to about 30%, such as in range from about 5% to about 15%, and dopants, such as boron, gallium, or the like, with a concentration in a range from about 5×10¹⁹ atoms/cm³ to about 5×10²¹ atoms/cm³. The third germanium concentration of the etch stop layers 105 may be lower than the first germanium concentration of the epitaxial source/drain regions 92 and the second germanium concentration of the sacrificial layers 95, which may result in the etch selectivity (e.g., the etch rate of the sacrificial layers 95 being larger than the etch rate of the etch stop layers 105) between the etch stop layers 105 and the sacrificial layers 95 in the p-type region 50P during the etching process which removes at least a portion of each sacrificial layer 95. In some embodiments, the etch stop layers 105 in the p-type region 50P comprise silicon and dopants, such as boron, or the like, with a concentration in a range from about 5×10²⁰ atoms/cm³ to about 5×10²² atoms/cm³. Such etch stop layers 105 may also have the aforementioned etch selectivity to the sacrificial layers 95 in the p-type region 50P during the etching process. As a result, the epitaxial source/drain regions 92 are protected by the etch stop layers 105 in the p-type region 50P during the etching process.

The etch stop layers 105 in the n-type region 50N may comprise silicon, silicon carbide, or the like. In some embodiments, the etch stop layers 105 in the n-type region 50N comprise silicon doped with phosphorus, arsenic, antimony, or the like, with a concentration in a range from about 5×10¹⁹ atoms/cm³ to about 1×10²¹ atoms/cm³. In some embodiments, in the n-type region 50N, the dopants in the sacrificial layers 95 comprise phosphorus and the dopants in the etch stop layers 105 comprise arsenic, which may result in the etch selectivity (e.g., the etch rate of the sacrificial layers 95 being larger than the etch rate of the etch stop layers 105) between the sacrificial layers 95 and the etch stop layers 105 in the n-type region 50N during etching process of the sacrificial layers 95. As a result, the epitaxial source/drain regions 92 are protected by the etch stop layers 105 in the n-type region 50N during the etching process.

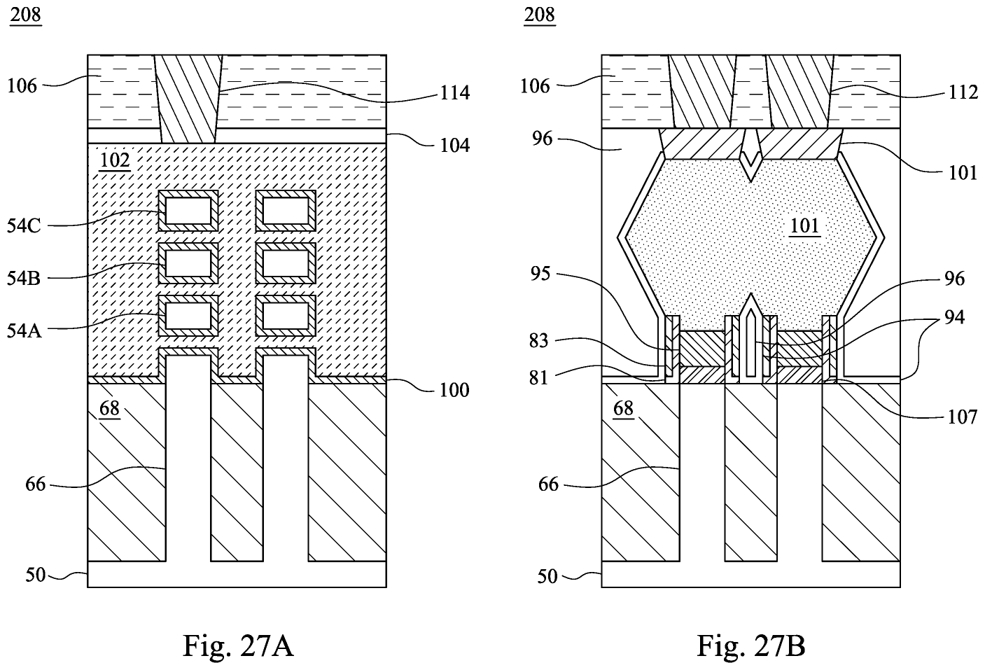

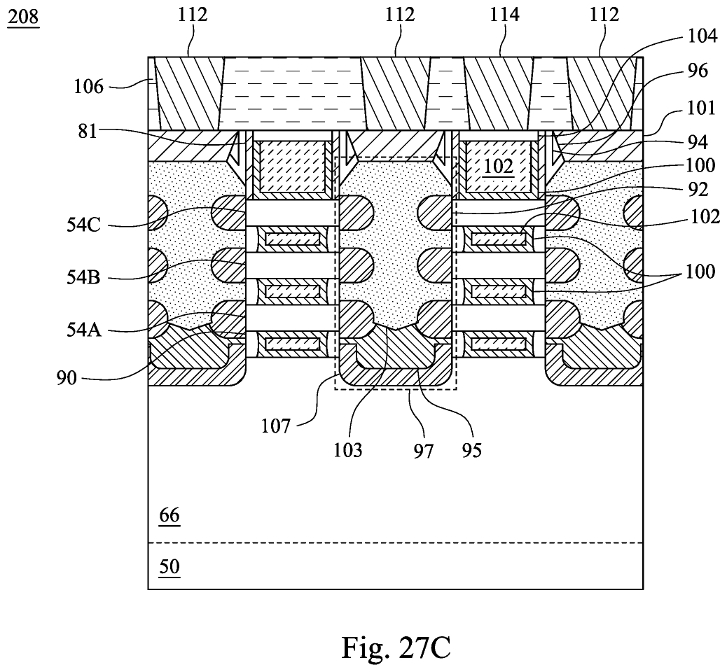

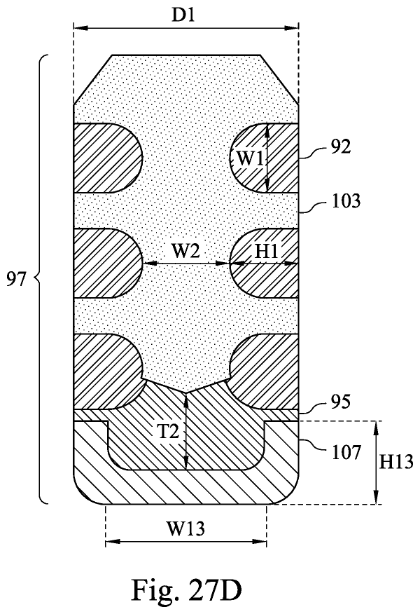

FIGS. 27A, 27B, 27C, and 27D show different cross-sections of a semiconductor device 208 similar to the cross-sections of the semiconductor device 200 shown in FIGS. 23A, 23B, and 23C, respectively, in accordance with some embodiments, wherein like reference numerals refer to like features. In the embodiments shown in FIGS. 27A, 27B, 27C, and 27D, in at least one of the areas 97, a semiconductor layer 107 is formed on the fin 66 and the sacrificial layer 95 is formed on the semiconductor layer 107. The semiconductor layer 107 and the epitaxial source/drain regions 92 may be formed during the same process and the semiconductor layer 107 may comprise the same or similar materials as the epitaxial source/drain regions 92. The semiconductor layer 107 may be U-shaped and in contact with the sacrificial layer 95, the first inner spacers 90, and the fin 66. The semiconductor layer 107 may have a height H13 in in a range from about 1 nm to about 30 nm and a flat bottom surface with a width W13 in a range from about 1 nm to about 30 nm. The sacrificial layer 95 may have a thickness T2 in a range from about 1 nm to about 60 nm. The semiconductor layer 107 in the p-type region 50P may induce strain on the adjacent second nanostructures 54, which may improve the performance of the semiconductor device 208.

The embodiments of the present disclosure have some advantageous features. By increasing the contact areas between the epitaxial source/drain regions 92 and the silicide layers 103, the electrical resistance between the epitaxial source/drain regions 92 and the source/drain contacts 112 may be reduced, thereby improving the performance of the semiconductor devices 200, 202, 204, 206, and 208.

In an embodiment, a semiconductor device includes a first plurality of nanostructures and a second plurality of nanostructures over a substrate; a first gate stack extending between the nanostructures of the first plurality of nanostructures and a second gate stack extending between the nanostructures of the second plurality of nanostructures; a first source/drain region in contact with a first nanostructure of the first plurality of nanostructures; a second source/drain region in contact with a first nanostructure of the second plurality of nanostructures, wherein the second source/drain region is separated from the first source/drain region; a silicide layer between the first source/drain region and the second source/drain region; and an isolation layer between the silicide layer and the substrate. In an embodiment, the semiconductor device further includes a material layer between the silicide layer and the isolation layer, wherein the material layer is in contact with the silicide layer and the isolation layer. In an embodiment, the material layer has a higher germanium concentration than the first source/drain region and the second source/drain region. In an embodiment, the material layer is doped with phosphorus, and wherein the first source/drain region and the second source/drain region are doped with arsenic. In an embodiment, the first source/drain region is in contact with a second nanostructure of the first plurality of nanostructures, wherein the first source/drain region extends continuously from the first nanostructure to the second nanostructure, and wherein the first nanostructure and the second nanostructure are separated by the first gate stack. In an embodiment, the silicide layer includes a first portion in contact with the first source/drain region and a second portion in contact with the second source/drain region, and wherein a metal layer is between the first portion and the second portion. In an embodiment, the semiconductor device further includes a first etch stop layer in contact with the first source/drain region and a second etch stop layer in contact with the second source/drain region, wherein the first etch stop layer is between the first source/drain region and the silicide layer and the second etch stop layer is between the second source/drain region and the silicide layer. In an embodiment, the first etch stop layer has a lower germanium concentration than the first source/drain region and the second etch stop layer has a lower germanium concentration than the second source/drain region.

In an embodiment, a semiconductor device includes a first plurality of nanostructures and a second plurality of nanostructures over a substrate; a first gate stack extending between the nanostructures of the first plurality of nanostructures and a second gate stack extending between the nanostructures of the second plurality of nanostructures; a first source/drain region along a sidewall of a first nanostructure of the first plurality of nanostructures; a second source/drain region along a sidewall of a first nanostructure of the second plurality of nanostructures; a silicide layer between the first source/drain region and the second source/drain region; and a material layer between the silicide layer and the substrate. In an embodiment, the material layer has a higher germanium concentration than the first source/drain region and the second source/drain region. In an embodiment, the semiconductor device further includes a third source/drain region along a sidewall of a second nanostructure of the first plurality of nanostructures, wherein the silicide layer is between the first source/drain region and the third source/drain region. In an embodiment, the semiconductor device further includes a semiconductor layer between the material layer and the substrate, wherein the material layer is between the first source/drain region and the semiconductor layer, and wherein the semiconductor layer includes a different material from the substrate. In an embodiment, the semiconductor device further includes an isolation layer between the material layer and the substrate.

In an embodiment, a method of forming a semiconductor device includes forming a first plurality of nanostructures and a second plurality of nanostructures over a substrate; forming a first source/drain region on a sidewall of a first nanostructure of the first plurality of nanostructures and forming a second source/drain region on a sidewall of a first nanostructure of the second plurality of nanostructures; forming a material layer on the first source/drain region and the second source/drain region; removing at least a portion of the material layer to form an opening; forming a metal layer in the opening; and annealing to form a silicide layer from the metal layer, the first source/drain region and the second source/drain region, and wherein the silicide layer is between the first source/drain region and the second source/drain region. In an embodiment, removing at least a portion of the material layer completely removes the material layer. In an embodiment, the material layer includes a semiconductor material, and wherein the material layer has a higher germanium concentration than the first source/drain region and the second source/drain region. In an embodiment, the material layer includes a dielectric material. In an embodiment, the method further includes forming a first etch stop layer on the first source/drain region and a second etch stop layer on the second source/drain region before forming the material layer. In an embodiment, the method further includes performing an oxidation treatment on the first etch stop layer and the second etch stop layer before forming the material layer. In an embodiment, the method further includes forming a dielectric layer over the substrate before forming the first source/drain region and the second source/drain region, wherein the material layer is between the dielectric layer and the silicide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first plurality of nanostructures and a second plurality of nanostructures over a substrate;
a first gate stack extending between the nanostructures of the first plurality of nanostructures and a second gate stack extending between the nanostructures of the second plurality of nanostructures;
a first source/drain region in contact with a first nanostructure of the first plurality of nanostructures;
a second source/drain region in contact with a first nanostructure of the second plurality of nanostructures, wherein the second source/drain region is separated from the first source/drain region;
a silicide layer between the first source/drain region and the second source/drain region; and
an isolation layer between the silicide layer and the substrate.

2. The semiconductor device of claim 1, further comprising a material layer between the silicide layer and the isolation layer, wherein the material layer is in contact with the silicide layer and the isolation layer.

3. The semiconductor device of claim 2, wherein the material layer has a higher germanium concentration than the first source/drain region and the second source/drain region.

4. The semiconductor device of claim 2, wherein the material layer is doped with phosphorus, and wherein the first source/drain region and the second source/drain region are doped with arsenic.

5. The semiconductor device of claim 1, wherein the first source/drain region is in contact with a second nanostructure of the first plurality of nanostructures, wherein the first source/drain region extends continuously from the first nanostructure to the second nanostructure, and wherein the first nanostructure and the second nanostructure are separated by the first gate stack.

6. The semiconductor device of claim 1, wherein the silicide layer comprises a first portion in contact with the first source/drain region and a second portion in contact with the second source/drain region, and wherein a metal layer is between the first portion and the second portion.

7. The semiconductor device of claim 1, further comprising a first etch stop layer in contact with the first source/drain region and a second etch stop layer in contact with the second source/drain region, wherein the first etch stop layer is between the first source/drain region and the silicide layer and the second etch stop layer is between the second source/drain region and the silicide layer.

8. The semiconductor device of claim 7, wherein the first etch stop layer has a lower germanium concentration than the first source/drain region and the second etch stop layer has a lower germanium concentration than the second source/drain region.

9. A semiconductor device comprising:
a first plurality of nanostructures and a second plurality of nanostructures over a substrate;
a first gate stack extending between the nanostructures of the first plurality of nanostructures and a second gate stack extending between the nanostructures of the second plurality of nanostructures;
a first source/drain region along a sidewall of a first nanostructure of the first plurality of nanostructures;
a second source/drain region along a sidewall of a first nanostructure of the second plurality of nanostructures;
a silicide layer between the first source/drain region and the second source/drain region; and
a material layer between the silicide layer and the substrate.

10. The semiconductor device of claim 9, wherein the material layer has a higher germanium concentration than the first source/drain region and the second source/drain region.

11. The semiconductor device of claim 9, further comprising a third source/drain region along a sidewall of a second nanostructure of the first plurality of nanostructures, wherein the silicide layer is between the first source/drain region and the third source/drain region.

12. The semiconductor device of claim 9, further comprising a semiconductor layer between the material layer and the substrate, wherein the material layer is between the first source/drain region and the semiconductor layer, and wherein the semiconductor layer comprises a different material from the substrate.

13. The semiconductor device of claim 9, further comprising an isolation layer between the material layer and the substrate.

14. A method of forming a semiconductor device, the method comprising:
forming a first plurality of nanostructures and a second plurality of nanostructures over a substrate;
forming a first source/drain region on a sidewall of a first nanostructure of the first plurality of nanostructures and forming a second source/drain region on a sidewall of a first nanostructure of the second plurality of nanostructures;
forming a material layer on the first source/drain region and the second source/drain region;
removing at least a portion of the material layer to form an opening;
forming a metal layer in the opening; and
annealing to form a silicide layer from the metal layer, the first source/drain region and the second source/drain region, and wherein the silicide layer is between the first source/drain region and the second source/drain region.

15. The method of claim 14, wherein removing at least a portion of the material layer completely removes the material layer.

16. The method of claim 14, wherein the material layer comprises a semiconductor material, and wherein the material layer has a higher germanium concentration than the first source/drain region and the second source/drain region.

17. The method of claim 14, wherein the material layer comprises a dielectric material.

18. The method of claim 14, further comprising forming a first etch stop layer on the first source/drain region and a second etch stop layer on the second source/drain region before forming the material layer.

19. The method of claim 18, further comprising performing an oxidation treatment on the first etch stop layer and the second etch stop layer before forming the material layer.

20. The method of claim 14, further comprising forming a dielectric layer over the substrate before forming the first source/drain region and the second source/drain region, wherein the material layer is between the dielectric layer and the silicide layer.
